(19) United States
(12) Patent Application Publication
(10) Pub. No.: US 2025/0204207 A1
(43) Pub. Date: Jun. 19, 2025

(54) TRANSPARENT DISPLAY DEVICE

(71) Applicant: LG Display Co., Ltd., Seoul (KR)

(72) Inventors: Taehee KO, Paju-si (KR); JongSung KIM, Paju-si (KR)

(21) Appl. No.: 18/922,895

(22) Filed: Oct. 22, 2024

(30) Foreign Application Priority Data
Dec. 15, 2023 (KR) 10-2023-0183505

(51) Int. Cl. H10K 59/80; H10K 59/123; H10K 59/35; H10K 102/10

(52) U.S. Cl. CPC H10K 59/80522; H10K 59/351; H10K 59/80521; H10K 59/80524; H10K 59/123; H10K 59/80516; H10K 2102/103

(57) ABSTRACT

A transparent display device according to an embodiment of the present disclosure includes a first area in which a plurality of sub-pixels is disposed and a second area in which the plurality of sub-pixels is not disposed. The display device includes a light emitting device disposed in the each of the plurality of sub-pixels. The light emitting device includes a first electrode, a light emission layer, and a second electrode. The display device includes a power line extending from the first area in a first direction. The display device includes a cathode connection electrode coupled to the power line in the first area and extended in a second direction toward the second area to be coupled to the second electrode of the light emitting device in the second area. The cathode connection electrode includes a bottom portion and at least one side portion extended from the bottom portion.

### CROSS-REFERENCE TO RELATED APPLICATIONS

This application claims the benefit of the Korean Patent Applications No. 10-2023-0183505 filed on Dec. 15, 2023, which are hereby incorporated by reference as if fully set forth herein.

### BACKGROUND

### Technical Field

The present disclosure relates to a transparent display device having a transmissive area within a display area.

### Description of the Related Art

With the development of the information society, the demand for display devices for displaying images is increasing in various forms. Accordingly, in recent years, various display devices such as Liquid Crystal Display LCD, Plasma Display Panel PDP, Quantum dot Light Emitting Display QLED, and Organic Light Emitting Display OLED have been utilized.

Recently, there has been active research on transparent display devices in which a user can see through the display device to view an object or image located on the opposite side. The transparent display device includes a display area on which images are displayed and a non-display area, and the display area can include a transmissive area capable of transmitting external light and a non-transmissive area. In the transparent display device, a light transmittance of the display area can be determined according to a light transmittance of the transmissive area.

### BRIEF SUMMARY

Various embodiments of the present disclosure is directed to providing a transparent display device, which substantially obviate one or more problems due to limitations and disadvantages of the related art.

Various embodiments of the present disclosure is directed to providing a transparent display device having high light transmittance.

Various embodiments of the present disclosure is directed to providing a transparent display device that can reduce the occurrence of failures due to moisture penetration.

Various embodiments of the present disclosure is directed to provide a transparent display device capable of implementing Environmental/Social/Governance ESG by reducing the generation of greenhouse gases due to the manufacturing process.

Additional advantages and features of the disclosure will be set forth in part in the description which follows and in part will become apparent to those having ordinary skill in the art upon examination of the following or can be learned from practice of the disclosure. Other benefits of the disclosure can be realized and attained by the structure particularly pointed out in the written description and claims hereof as well as the appended drawings.

A transparent display device according to an embodiment of the present disclosure includes a first area in which a plurality of sub-pixels are disposed; a second area in which the plurality of sub-pixels are not disposed; a light emitting device disposed in the each of the plurality of sub-pixels and comprising a first electrode, a light emission layer, and a second electrode; a power line extending from the first area in a first direction; and a cathode connection electrode connected to the power line in the first area and extended in a second direction toward the second area to be electrically connected to the second electrode of the light emitting device in the second area, wherein the cathode connection electrode comprises a bottom portion and at least one side portion extended from the bottom.

In another aspect of the present disclosure, there is provided a transparent display device according to another embodiment of the present disclosure includes a substrate comprising a display area and a non-display area disposed outside the display area, the display area having a transmissive area and a non-transmissive area; a light emitting device disposed in the non-transmissive area on the substrate, and comprising a first electrode, a light emission layer, and a second electrode; a power line extended in a first direction in the non-transmissive area; and a cathode connection electrode electrically connected to the power line, extended in the second direction toward the transmissive area, and comprising transparent conductive materials, wherein the second electrode of the light emitting device is extended from the non-transmissive area to the transmissive area, and is connected to the cathode connection electrode in the transmissive area.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a perspective view schematically illustrating a transparent display device according to one embodiment of the present disclosure;

FIG. 2 is a plan view schematically illustrating a transparent display panel according to one embodiment of the present disclosure;

FIG. 3 is a diagram schematically illustrating one embodiment of the pixels disposed in portion A illustrated in FIG. 2;

FIG. 4 is a drawing illustrating one embodiment of a plurality of sub-pixels and a plurality of signal lines disposed in the portion B illustrated in FIG. 3;

FIG. 5 is a circuit diagram illustrating one example of the sub-pixel illustrated in FIG. 4;

FIG. 6 is a cross-sectional view illustrating one example of I-I′ shown in the sub-pixel illustrated in FIG. 4;

FIG. 7 is an enlarged plan view of one embodiment of a common power line and cathode connection electrode;

FIG. 8 is a cross-sectional view illustrating one embodiment of II-II′ illustrated in FIG. 7;

FIG. 9 is a cross-sectional view illustrating one embodiment of III-III′ illustrated in FIG. 7;

FIGS. 10A to 10G illustrates one example of a method of forming the cathode connection electrode illustrated in FIG. 9;

FIG. 11 is an enlarged plan view of one example of a plurality of pads disposed in a pad area;

FIG. 12 is a cross-sectional view illustrating one embodiment of IV-IV′ illustrated in FIG. 11;

FIG. 13 is a cross-sectional view illustrating another embodiment of III-III′ illustrated in FIG. 7;

FIGS. 14A to 14G illustrates one example of a method of forming the cathode connection electrode illustrated in FIG. 13;

FIG. 15 is a cross-sectional view illustrating another embodiment of III-III′ illustrated in FIG. 7;

FIG. 16 is an enlarged plan view of another embodiment of a common power line and cathode connection electrode;

FIG. 17 is a cross-sectional view illustrating one embodiment of V-V′ illustrated in FIG. 16;

FIG. 18 is a cross-sectional view illustrating one embodiment of VI-VI′ illustrated in FIG. 16;

FIG. 19 is a drawing illustrating another embodiment of the plurality of sub-pixels and plurality of signal lines disposed in the portion B illustrated in FIG. 3;

FIG. 20 is an enlarged plan view of another embodiment of a common power line and cathode connection electrode;

FIG. 21 is a cross-sectional view illustrating one embodiment of VII-VII′ illustrated in FIG. 20; and

FIG. 22 is a cross-sectional view illustrating one embodiment of VIII-VIII′ illustrated in FIG. 20.

### DETAILED DESCRIPTION

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art. Further, the present disclosure is only defined by scopes of claims.

A shape, a size, a dimension (e.g., length, width, height, thickness, radius, diameter, area, etc.), a ratio, an angle, and a number disclosed in the drawings for describing embodiments of the present disclosure are merely an example, and thus, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In the following description, when the detailed description of the relevant known function or configuration is determined to unnecessarily obscure the important point of the present disclosure, the detailed description will be omitted. In a case where ‘comprise,’ ‘have,’ and ‘include’ described in the present specification are used, another part can be added unless ‘only˜’ is used. The terms of a singular form can include plural forms unless referred to the contrary.

In construing an element, the element is construed as including an error range although there is no explicit description.

In describing a position relationship, for example, when a position relation between two parts is described as ‘on˜,’ ‘over˜,’ ‘under˜,’ and ‘next˜,’ one or more other parts can be disposed between the two parts unless ‘just’ or ‘direct’ is used.

In describing a time relationship, for example, when the temporal order is described as ‘after˜,’ ‘subsequent˜,’ ‘next˜,’ and ‘before˜,’ a case which is not continuous can be included unless ‘just’ or ‘direct’ is used.

It will be understood that, although the terms “first,” “second,” etc., can be used herein to describe various elements, these elements should not be limited by these terms. These terms are only used to distinguish one element from another. Accordingly, a first element mentioned hereinafter could be termed a second element without departing from the scope of the present disclosure.

The term “at least one” should be understood as including any and all combinations of one or more of the associated listed items. For example, the meaning of “at least one of a first item, a second item, and a third item” denotes each of the first item, the second item, and the third item as well as the combination of all items proposed from two or more of the first item, the second item, and the third item.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth clement. Here, the second element may be included in at least one of two or more elements that “are connected or coupled to”, “contact or overlap”, etc. each other.

Features of various embodiments of the present disclosure can be partially or overall coupled to or combined with each other and can be variously inter-operated or combined with each other and driven technically as those skilled in the art can sufficiently understand. The embodiments of the present disclosure can be carried out independently from each other, or can be carried out together in co-dependent relationship.

Hereinafter, preferred examples of transparent display device according to the present disclosure will be described in detail with reference to the accompanying drawings. In assigning reference numerals to the components in each drawing, the same component can have the same numeral as far as possible, even if shown in different drawings. In addition, in describing the present disclosure, specific descriptions of related disclosed configurations or features can be omitted if it is determined that such detailed description would obscure the spirit of the present disclosure.

Hereinafter, preferred embodiments of the present disclosure will be described in detail with reference to the accompanying drawings.

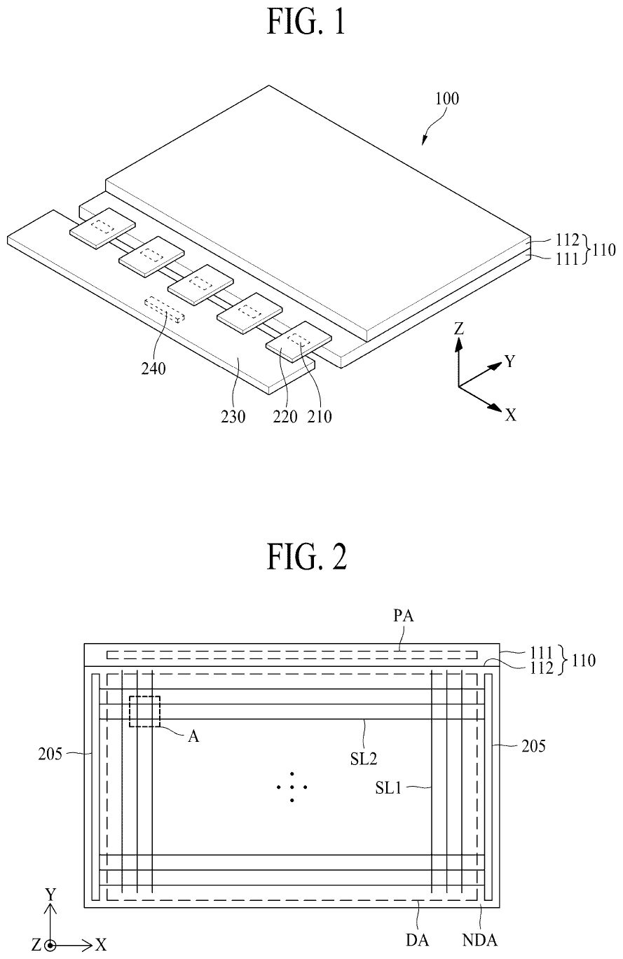

FIG. 1 is a perspective view schematically illustrating a transparent display device according to one embodiment of the present disclosure, and FIG. 2 is a top view schematically illustrating a transparent display panel according to one embodiment of the present disclosure.

Hereinafter, the X-axis represents a direction parallel to a scan line, the Y-axis represents a direction parallel to a data line, and the Z-axis represents a height direction of the transparent display device 100.

While the transparent display device 100 according to embodiments of the present disclosure has been described with emphasis on its implementation as an Organic Light Emitting Display, it can also be implemented as a Liquid Crystal Display, a Quantum dot Lighting Emitting Display, or an Electrophoresis display.

Referring to FIGS. 1 and 2, a transparent display device 100 according to one embodiment of the present disclosure includes a transparent display panel 110, a source drive integrated circuit (hereinafter referred to as “IC”) 210, a flexible film 220, a circuit board 230, and a timing controller 240.

The transparent display panel 110 includes a first substrate 111 and a second substrate 112 facing each other. The second substrate 112 can be an encapsulation substrate. The first substrate 111 can be a plastic film, a glass substrate, or a silicon wafer substrate formed using a semiconductor process. The second substrate 112 can be a plastic film, a glass substrate, or an encapsulation film. These first substrate 111 and second substrate 112 can include a transparent material.

The transparent display panel 110 can be divided into a display area DA, in which pixels are included to display images, and a non-display area NDA, which does not display images.

The display area DA can be provided with first signal lines SL1, second signal lines SL2, and pixels, and the non-display area NDA can be provided with a pad area PA on which pads are disposed and at least one scan driver 205.

The first signal lines SL1 can be extended in a first direction (e.g., in the Y-axis direction) and can intersect with the second signal lines SL2 in the display area DA. The second signal lines SL2 can be extended in the display area DA in a second direction (e.g., in the X-axis direction). The pixels are provided in the area where the first signal line SL1 is disposed or in an area where the first signal line SL1 and the second signal line SL2 intersect, and emit a predetermined light to display the images.

A plurality of pads can be disposed in the pad area PA. Since the size of the first substrate 111 is larger than the size of the second substrate 112, a portion of the first substrate 111 can be exposed without being covered by the second substrate 112. The portion of the first substrate 111 that is exposed and not covered by the second substrate 112 can be provided with pads, such as power pads, data pads, and the like.

The scan drivers 205 are connected to the scan lines and supply scan signals. The scan driver 205 can be formed in a gate driver in panel GIP type on the non-display area NDA outside one or both sides of the display area DA of the transparent display panel 110. Alternatively, the scan driver 205 can be manufactured as a driver chip, mounted on a flexible film, and attached to the non-display area NDA on outside one or both sides of the display area DA of the transparent display panel 110 in a tape automated bonding TAB type.

The source drive IC 210 is supplied with digital video data and data control signals from the timing controller 240. The source drive IC 210 converts the digital video data into analog data voltages according to the data control signals and supplies them to the data lines. When the source drive IC 210 is manufactured as a driving chip, it can be mounted on the flexible film 220 in a Chip On Film COF type or Chip On Plastic COP type.

Lines connecting the pads to the source drive IC 210, and lines connecting the pads to the lines of the circuit board 230 can be formed on the flexible film 220. The flexible film 220 can be attached onto the pads using an anisotropic conducting film, thereby connecting the pads and the lines of the flexible film 220.

The circuit board 230 can be attached to the flexible film 220. The circuit board 230 can be mounted with a plurality of circuits implemented as driving chips. For example, the timing controller 240 can be mounted on the circuit board 230. The circuit board 230 can be a printed circuit board or a flexible printed circuit board.

The timing controller 240 is supplied with digital video data and timing signals from an external system board. Based on the timing signals, the timing controller 240 generates scan control signals for controlling the timing of operation of the scan driver 205 and data control signals for controlling the source drive ICs 210. The timing controller 240 supplies the scan control signals to the scan driver 205 and the data control signals to the source drive ICs 210.

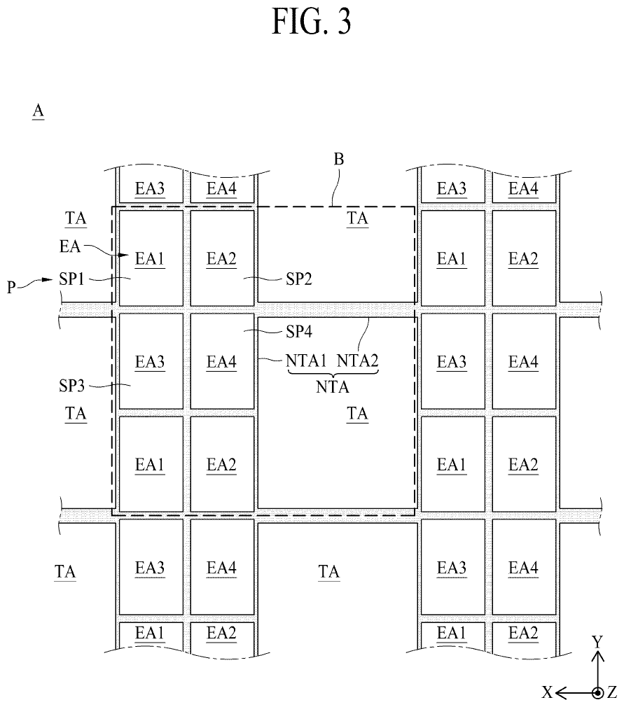

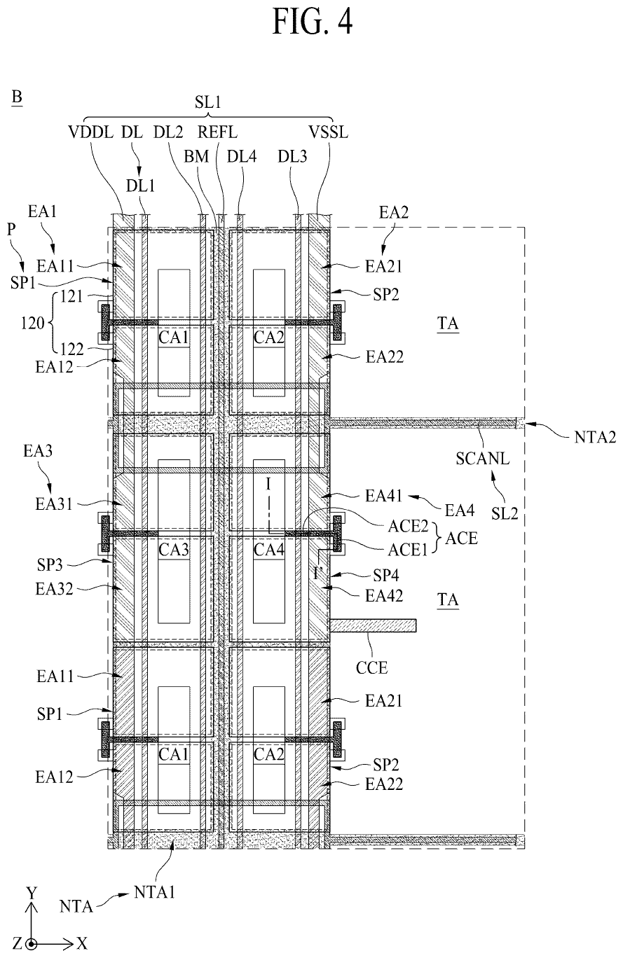

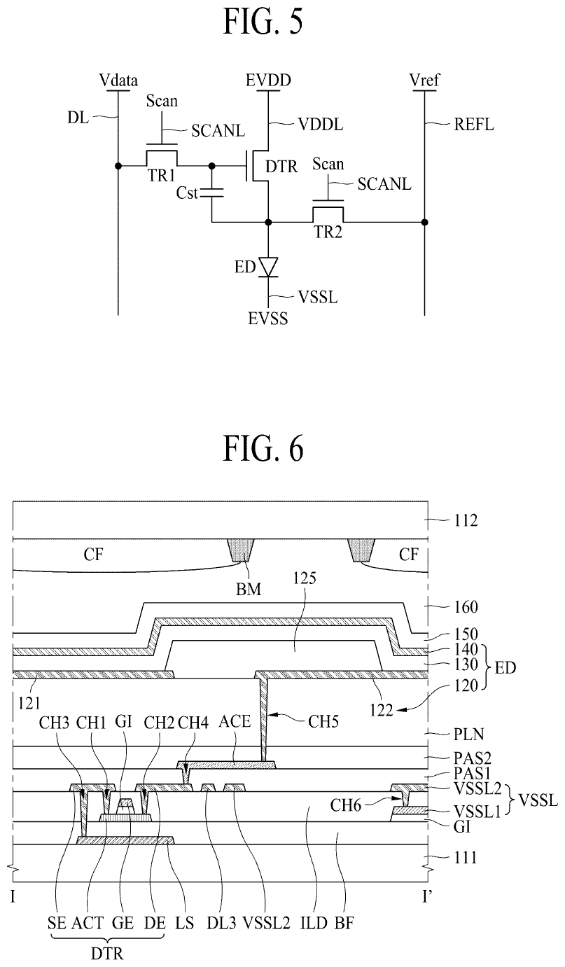

FIG. 3 is a diagram schematically illustrating one embodiment of the pixels disposed in region A illustrated in FIG. 2, FIG. 4 is a drawing to illustrate one embodiment of a plurality of sub-pixels and a plurality of signal lines disposed in the B region illustrated in FIG. 3, FIG. 5 is a schematic to illustrate one example of the sub-pixel illustrated in FIG. 4, and FIG. 6 is a cross-sectional view illustrating one example of I-I′ shown in the sub-pixel illustrated in FIG. 4.

The transparent display panel 110 according to one embodiment of the present disclosure can include the display area DA and the non-display area NDA illustrated in FIG. 2. As shown in FIG. 3, the display area DA can include a first area TA in which a plurality of sub-pixels SP1, SP2, SP3, and SP4 are disposed, and a second area NTA in which the plurality of sub-pixels SP1, SP2, SP3, and SP4 are not disposed. The first area TA can be a transmissive area through which most of the light incident from the outside passes. The second area NTA can be a non-transmissive area that does not transmit most of the light incident from the outside. In one example, the transmissive area TA can be an area having a light transmittance greater than α%, and the non-transmissive area NTA can be an area having a light transmittance less than β%. In this example, a is greater than β, and each of α and β can be a positive number. The transparent display panel 110 can allow users to see an object or background scenes that are located on a rear surface of the transparent display panel 110 due to the transmissive areas TA.

The non-transmissive area NTA can include a first non-transmissive area NTA1, a second non-transmissive area NTA2, and a pixel P.

As shown in FIGS. 3 and 4, the first non-transmissive area NTA1 can be extended from the display area DA in the first direction (e.g., Y-axis direction), and can be disposed to at least partially overlap with the emission areas EA1, EA2, EA3, and EA4. The transparent display panel 110 can include a plurality of first non-transmissive areas NTA1 spaced apart from each other, and a transmissive area TA can be provided between two adjacent first non-transmissive areas NTA1. In each first non-transmissive area NTA1, the first signal lines SL1 extended in the first direction (e.g., Y-axis direction) can be spaced apart from each other.

The first signal lines SL1 can include a common power line VSSL. In an embodiment, the first signal lines SL1 can further include at least one of a reference line REFL, data lines DL1, DL2, DL3, and DL4, and a pixel power line VDDL.

The pixel power line VDDL can supply first power to a driving transistor DTR of each of the sub-pixels SP1, SP2, SP3, and SP4 disposed in the display area DA.

The common power line VSSL can supply a second power to the cathode electrode of the sub-pixels SP1, SP2, SP3, and SP4 disposed in the display area DA. In this example, the second power can be a common power being supplied in common to the sub-pixels SP1, SP2, SP3, and SP4.

The reference line REFL can supply an initialization voltage (or reference voltage) to the driving transistor DTR of each of the sub-pixels SP1, SP2, SP3, and SP4 provided in the display area DA. In one embodiment, the reference line REFL can be disposed between the plurality of data lines DL1, DL2, DL3, and DL4. In one example, the reference line REFL can be disposed in the center of the plurality of data lines DL1, DL2, DL3, and DL4.

Each of the data lines DL1, DL2, DL3, and DL4 can supply a data voltage to the sub-pixels SP1, SP2, SP3, and SP4. In one example, the first data line DL1 can supply a first data voltage to a first driving transistor of the first sub-pixel SP1, the second data line DL2 can supply a second data voltage to a second driving transistor of the second sub-pixel SP2, the third data line DL3 can supply a third data voltage to a third driving transistor of the third sub-pixel SP3, and the fourth data line DL4 can supply a fourth data voltage to a fourth driving transistor of the fourth sub-pixel SP4.

The transparent display panel 110 according to one embodiment of the present disclosure can be provided with pixels P between adjacent transmissive areas TA, and the pixels P can include emission areas EA1, EA2, EA3, and EA4 in which light emitting elements are disposed to emit light. In the transparent display panel 110, since an area of the non-transmissive area NTA is small, the circuit elements can be disposed to overlap the emission areas EA1, EA2, EA3, and EA4. That is, the emission areas EA1, EA2, EA3, and EA4 can overlap at least partially with the circuit areas CA1, CA2, CA3, and CA4 in which the circuit elements are disposed.

In one example, the circuit areas can include a first circuit area CA1 in which circuit elements connected to the first sub-pixel SP1 are disposed, a second area CA2 in which circuit elements connected to the second sub-pixel SP2 are disposed, a third area CA3 in which circuit elements connected to the third sub-pixel SP3 are disposed, and a fourth area CA4 in which circuit elements connected to the fourth sub-pixel SP4 are disposed.

The second non-transmissive area NTA2 can be extended in the second direction (e.g., X-axis direction) between two adjacent first non-transmissive areas NTA1. The second non-transmissive area NTA2 can be disposed between two adjacent transmissive areas TA. In the transparent display panel 110, a plurality of second non-transmissive areas NTA2 can be spaced apart from each other, and the transmissive area TA can be disposed between two adjacent second non-transmissive areas NTA2. In the second non-transmissive areas NTA2, the second signal line SL2 can be disposed.

The second signal line SL2 can be extended in the second direction (e.g., X-axis direction). For example, the second signal line SL2 can include the scan line SCANL. The scan line SCANL can supply the scan signals to the sub-pixels SP1, SP2, SP3, and SP4 of the pixel P. An organic film such as a bank can be formed on the second signal line SL2, but is not necessarily limited thereto.

Each of the pixels P is disposed in the first non-transmissive area NTA1, and emits light to display images. The emission area EA can correspond to the area where the pixels Pemit light.

As shown in FIGS. 3 and 4, each of the pixels P can include the first sub-pixel SP1, the second sub-pixel SP2, the third sub-pixel SP3, and the fourth sub-pixel SP4. The first sub-pixel SP1 can include a first emission area EA1 emitting a first color light, and the second sub-pixel SP2 can include a second emission area EA2 emitting a second color light. The third sub-pixel SP3 can include a third emission area EA3 emitting a third color light, and the fourth sub-pixel SP4 can include the fourth emission area EA4 emitting a fourth color light.

For example, the first emission area EA1 can emit white light, the second emission area EA2 can emit green light. The third emission area EA3 can emit red light, and the fourth emission area EA4 can emit blue light. However, this is not necessarily limited. Further, the arrangement order of each sub-pixel SP1, SP2, SP3, and SP4 can be modified variously.

On the other hand, each of the emission areas EA1, EA2, EA3, and EA4 disposed in each of the plurality of sub-pixels SP1, SP2, SP3, and SP4 can be divided in plural. Specifically, each of the emission areas EA1, EA2, EA3, and EA4 disposed in the first sub-pixel SP1, the second sub-pixel SP2, the third sub-pixel SP3, and the fourth sub-pixel SP4 can be divided into two and can include a first divided emission area EA11, EA21, EA31, and EA41 and a second divided emission area EA12, EA22, EA32, and EA42.

As shown in FIG. 5, each of the first sub-pixel SP1, the second sub-pixel SP2, the third sub-pixel SP3, and the fourth sub-pixel SP4 can be provided with a light emitting device ED and a circuit element having a 3T (Transistor) 1C (Capacitor) structure including a first switching transistor TR1, a second switching transistor TR2, the driving transistor DTR, and a capacitor Cst, but not necessarily limited thereto. Each of the sub-pixels SP1, SP2, SP3, and SP4 can further include a compensation circuit, and in this example, the circuit element can have various structures such as 4T2C, 5T2C, 6T1C, 6T2C, 7T1C, 7T2C, etc.

Each of the transistors DTR, TR1, and TR2 of each of the sub-pixels SP1, SP2, SP3, and SP4 can include a gate electrode, a source electrode, and a drain electrode. Since the source electrode and the drain electrode are not fixed and can change depending on the direction of the voltage and current applied to the gate electrode, one of the source electrode and the drain electrode can be represented as the first electrode and the other can be represented as the second electrode. The transistors DTR, TR1, and TR2 of each sub-pixel SP1, SP2, SP3, and SP4 can utilize at least one of a polysilicon semiconductor, an amorphous silicon semiconductor, and an oxide semiconductor. The transistors DTR, TR1, and TR2 can be P-type or N-type, or a mixture of P-type and N-type.

The first switching transistor TR1 can supply a data voltage Vdata supplied from the data line DL to the driving transistor DTR. Specifically, the first switching transistor TR1 can charge the capacitor Cst with the data voltage Vdata supplied from the data line DL. For this purpose, the first switching transistor TR1 can have the gate electrode connected to the scan line SCANL and the first electrode connected to the data line DL. Further, the first switching transistor TR1 can have the second electrode connected to one end of the capacitor Cst and the gate electrode of the driving transistor DTR.

The first switching transistor TR1 can be turned on in response to the scan signal Scan applied through the scan line SCANL. When the first switching transistor TR1 is turned on, the data voltage Vdata applied through the data line DL can be transmitted to the end of the capacitor Cst.

The second switching transistor TR2 can supply a reference voltage Vref supplied from the reference line REFL to the driving transistor DTR. Specifically, the second switching transistor TR can have the gate electrode connected to the scan line SCANL and the first electrode connected to the reference line REFL. Further, the second switching transistor TR2 can have the second electrode connected to the first electrode of the driving transistor DTR and the other end of the capacitor Cst.

The second switching transistor TR2 can be turned on in response to the scan signal Scan applied through the scan line SCANL. When the second switching transistor TR2 is turned on, the reference voltage Vref applied through the reference line REFL can be transmitted to the other end of the capacitor Cst. In addition, the reference voltage Vref can also be applied to the source electrode of the driving transistor DTR.

The capacitor Cst can maintain the data voltage Vdata to be supplied to the driving transistor DTR for one frame. Specifically, the capacitor Cst can have a first electrode connected to the gate electrode of the driving transistor DTR and a second electrode connected to the source electrode of the driving transistor DTR. The capacitor Cst can store a voltage corresponding to the data voltage Vdata transmitted through the first switching transistor TR1, and can turn on the driving transistor DTR with the stored voltage.

The driving transistor DTR can generate a data current from the first power source EVDD supplied from the pixel power line VDDL to supply to the anode electrode of the light emitting element ED. Specifically, the driving transistor DTR can have the gate electrode connected to one end of the capacitor Cst and the first electrode connected to the pixel power line VDDL. Further, the driving transistor DTR can have the second electrode connected to the anode electrode of the light emitting element ED.

The driving transistor DTR can be turned on in response to a data voltage charged on the capacitor Cst. When the driving transistor DTR is turned on, the first power source EVDD applied through the pixel power line VDDL can be transmitted to the anode electrode of the light emitting element ED.

The light emitting device ED can include the anode electrode connected to the driving transistor DTR, the cathode electrode being supplied with a second power source EVSS from the common power line VSSL, and the light emission layer between the anode electrode and the cathode electrode. The anode electrode can be an independent electrode for each light emitting device, while the cathode electrode can be a common electrode shared by all light emitting devices. When the light emitting device ED is supplied with a driving current from the driving transistor DTR, electrons from the cathode electrode are injected into the light emission layer, and holes from the anode electrode are injected into the light emission layer, and the fluorescent or phosphorescent material can emit light due to the recombination of the electrons and holes in the light emission layer, thus light can be generated with a brightness proportional to a current value of the driving current.

The anode electrode of the light emitting device ED can be connected to the second electrode of the driving transistor DTR, and the cathode electrode of the light emitting device ED can be connected to the common power line VSSL. The light emitting device ED can emit light in response to the driving current generated by the driving transistor DTR.

Hereinafter, with reference to FIG. 6, a configuration of a circuit element and a light emitting device ED disposed in the non-transmissive area NTA will be described in more detail.

Referring to FIG. 6, the light shield layer LS can be disposed on the first substrate 111. The light shield layer LS can block external light incident on an active layer ACT in the area where the driving transistor DTR is disposed. The light shield layer LS can be formed as a single layer or multiple layers consisting of any one of molybdenum Mo, aluminum Al, chromium Cr, gold Au, titanium Ti, nickel Ni, neodymium Nd, and copper Cu, or an alloy thereof.

A buffer layer BF can be disposed on the light shield layer LS. The buffer layer BF can protect the driving transistor DTR from impurities such as hydrogen, moisture, etc., that penetrate through the first substrate 111, which is vulnerable to moisture permeation, and can have a single-layer or multi-layer structure including an inorganic insulation material such as silicon oxide SiOx, silicon nitride SiNx, aluminum oxide Al2O3.

The driving transistor DTR can be disposed on the buffer layer BF. The driving transistor DTR can include the active layer ACT, the gate electrode GE, the source electrode SE, and the drain electrode DE disposed on the buffer layer BF.

A gate insulation layer GI can be disposed between the active layer ACT and the gate electrode GE. As shown in FIG. 6, the gate insulation layer GI can be patterned only in the area where the gate electrode GE is provided, but is not necessarily limited thereto. In other embodiments, the gate insulation layer GI can be formed to cover the active layer ACT.

An interlayer insulation layer ILD can be disposed between the gate electrode GE and the source electrode SE and between the gate electrode GE and the drain electrode DE. The source electrode SE and the drain electrode DE of the driving transistor DTR can be connected to the source area and the drain area of the active layer ACT through each of the first contact hole CH1 and the second contact hole CH2, respectively, which penetrate the interlayer insulation layer ILD.

On the other hand, one of the source electrodes SE and drain electrodes DE of the driving transistor DTR can be connected to the light shield layer LS through a third contact hole CH3 that penetrates the interlayer insulation layer ILD and the buffer layer BF. The light shield layer LS can be electrically connected with one of the source electrode SE and the drain electrode DE of the driving transistor DTR not to operate as a floating gate. When the light shield layer LS is floated without being connected to the other electrodes, the threshold voltage of the driving transistor DTR can be varied by the floated light shield layer LS. The transparent display panel 110 according to one embodiment of the present disclosure can minimize the threshold voltage fluctuation of the driving transistor DTR by electrically connecting the light shield layer LS with one of the source electrode SE and the drain electrode DE of the driving transistor DTR. In FIG. 6, it is illustrated that the light shield layer LS is connected to the source electrode SE of the driving transistor DTR, but is not limited thereto. The light shield layer LS can also be connected to the drain electrode DE of the driving transistor DTR.

The active layer ACT can be formed of a silicon-based semiconductor material or an oxide-based semiconductor material. The gate electrode GE, the source electrode SE, and the drain electrode DE can be formed as a single-layer or multiple layers consisting of any one of molybdenum Mo, aluminum Al, chromium Cr, gold Au, titanium Ti, nickel Ni, neodymium Nd, and copper Cu, or an alloy thereof.

The gate insulation layer GI and interlayer insulation layer ILD can have a single-layer or multi-layer structure including inorganic insulating materials such as silicon oxide SiOx, silicon nitride SiNx, and aluminum oxide Al2O3.

In the transparent display panel 110 according to one embodiment of the present disclosure, at least some of the pixel power lines VDDL, the common power lines VSSL, the reference lines REFL, the data lines DL, and the scan lines SCANL can be disposed on the same layer as any one of the gate electrodes GE, the source electrodes SE, and the drain electrodes DE of the driving transistors DTR. In one example, the data lines DL and the common power lines VSSL can be formed of the same materials on the same layer as any one of the gate electrode GE, source electrode SE, and drain electrode DE of the driving transistors DTR, but are not necessarily limited thereto. In one example, the common power line VSSL can include a plurality of layers VSSL1 and VSSL2. Among the plurality of layers, the first metal layer VSSL1 can be formed of the same material on the same layer as the gate electrode GE of the driving transistors DTR, and the second metal layer VSSL2 can be formed of the same material on the same layer as the source electrode SE of the driving transistors DTR. In this example, the second metal layer VSSL2 can be electrically connected to the first metal layer VSSL1 through a sixth contact hole CH6 penetrating the interlayer insulation layer ILD.

A first insulation layer PAS1 can be disposed on the driving transistor DTR, and a second insulation layer PAS2 can be disposed on the first insulation layer PAS1. The first insulation layer PAS1 and the second insulation layer PAS2 can be disposed in the non-transmissive area NTA and cannot be disposed in at least a portion of the transmissive area TA. That is, the first insulation layer PAS1 and the second insulation layer PAS2 can include an opening area overlapping with at least a portion of the transmissive area TA. The first insulation layer PAS1 and the second insulation layer PAS2 can cause refraction of light as light transmits through them, which can impair transparency. Accordingly, the transparent display panel 110 according to one embodiment of the present disclosure can increase transparency by removing a portion of the first insulation layer PAS1 and the second insulation layer PAS2 from the transmissive area TA.

The first insulation layer PAS1 and the second insulation layer PAS2 can have a single-layer or multi-layer structure including an inorganic insulating material such as silicon oxide SiOx, silicon nitride SiNx, or aluminum oxide Al2O3.

An anode connection electrode ACE can be separately disposed between the first insulation layer PAS1 and the second insulation layer PAS2. The anode connection electrode ACE can include a transparent conductive material. In one example, the anode connection electrode ACE can be one of ITO and IZO, but not necessarily limited to.

A planarization layer PLN can be disposed on the second insulation layer PAS2 to planarize a step difference caused by the driving transistor DTR. The planarization layer PLN can be disposed in the non-transmissive area NTA and cannot be disposed in at least a portion of the transmissive area TA. That is, the planarization layer PLN can include an opening area overlapping at least a portion of the transmissive area TA. The planarization layer PLN can cause refraction of light as light transmits through it, which can impair transparency. Accordingly, the transparent display panel 110 according to one embodiment of the present disclosure can increase transparency by removing a portion of the planarization layer PLN from the transmissive area TA.

The planarization layers PLNs can include organic films such as acryl resin, epoxy resin, phenolic resin, polyamide resin, polyimide resin, and the like.

The light emitting device ED and the bank BN can be disposed on the planarization layer PLN. The light emitting device ED can include the first electrode 120, the light emission layer 130, and the second electrode 140.

The first electrode 120 can be disposed on the planarization layer PLN and electrically connected to the driving transistor DTR. Specifically, the first electrode 120 can be connected to the anode connection electrode ACE through a fifth contact hole CH5 penetrating the planarization layer PLN and the second insulation layer PAS2. The anode connection electrode ACE can be connected to the source electrode SE or the drain electrode DE of the driving transistor DTR through a fourth contact hole CH4 penetrating the first insulation layer PAS1. As a result, the first electrode 120 can be electrically connected to the source electrode SE or the drain electrode DE of the driving transistor DTR through the anode connection electrode ACE.

The first electrode 120 can be disposed for each sub-pixel SP1, SP2, SP3, and SP4, and cannot be disposed in the transmissive area TA. The first electrode 120 can include a highly reflective metallic material, such as a stacked structure of aluminum and titanium Ti/Al/Ti, a stacked structure of aluminum and ITO ITO/Al/ITO, an Ag alloy, a stacked structure of Ag alloy and ITO ITO/Ag alloy/ITO, a MoTi alloy, and a stacked structure of MoTi alloy and ITO ITO/MoTi alloy/ITO. Ag alloys can be alloys of silver Ag, palladium Pd, and copper Cu. The MoTi alloy can be an alloy of molybdenum Mo and titanium Ti. The first electrode 120 can be the anode electrode of the light emitting device ED.

On the other hand, the first electrode 120 can be divided in plural in each of the plurality of sub-pixels SP1, SP2, SP3, and SP4. In one example, the first electrode 120 can include a first divided electrode 121 and a second divided electrode 122. The first divided electrode 121 can be disposed in a first divided emission area EA11, EA21, EA31, and EA4, and the second divided electrode 122 can be disposed in a second divided emission area EA12, EA22, EA32, and EA42. The first divided electrode 121 and the second divided electrode 122 can be spaced apart from each other on the same layer.

The first divided electrode 121 and the second divided electrode 122 can be electrically connected to each other through the anode connection electrode ACE. As shown in FIG. 4, the anode connection electrode ACE can include a first anode connection electrode ACE1 and a second anode connection electrode ACE2. One end of the first anode connection electrode ACE1 can be electrically connected to the first divided electrode 121 and the other end of the first anode connection electrode ACE1 can be electrically connected to the second divided electrode 122, thereby electrically connecting the first divided electrode 121 and the second divided electrode 122. The second anode connection electrode ACE2 can protrude from one side of the first anode connection electrode ACE1 to be extended toward the circuit area CA in which the driving transistor DTR is disposed. One end of the second anode connection electrode ACE2 can be electrically connected to the first anode connection electrode ACE1 and the other end of the second anode connection electrode ACE2 can be electrically connected to the source electrode SE or the drain electrode DE of the driving transistor DTR. Thereby, the first divided electrode 121 and the second divided electrode 122 can be electrically connected to each other through the first anode connection electrode ACE1 and electrically connected to the source electrode SE or the drain electrode DE of the driving transistor DTR through the second anode connection electrode ACE2.

In the transparent display panel 110 according to one embodiment of the present disclosure, the anode connection electrode ACE can be protruded toward the transmissive area TA to contact each of the first divided electrode 121 and the second divided electrode 122. In the transparent display panel 110 according to one embodiment of the present disclosure, since the anode connection electrode ACEs can include a transparent conductive material, the anode connection electrode ACE can be formed without loss of light transmittance of the transmissive area TA.

The bank 125 can be disposed on the planarization layer PLN. Further, the bank 125 can be disposed between the first electrodes 120. Also, the bank 125 can be disposed to cover an edge of each of the first electrodes 120 and to expose a portion of each of the first electrodes 120. Accordingly, the bank 125 can prevent a problem in which light emission efficiency is lowered due to the concentration of current at the ends of each of the first electrodes 120.

The bank 125 can define the emission areas EA1, EA2, EA3, and EA4 for each of the sub-pixels SP1, SP2, SP3, and SP4. The emission areas EA1, EA2, EA3, and EA4 of each of the sub-pixels SP1, SP2, SP3, and SP4 represent areas where the first electrode 120, the light emission layer 130, and the second electrode 140 are stacked sequentially and holes from the first electrode 120 and electrons from the second electrode 140 are combined with each other in the light emission layer 130 and emit light. In this example, an area in which the bank 125 is disposed does not emit light and thus becomes the non-emission area NEA, and an area in which the bank 125 is not disposed and the first electrode 120 is exposed can become the emission area EA1, EA2, EA3, and EA4.

The bank 125 can include an organic film, such as an acrylic resin, epoxy resin, phenolic resin, polyamide resin, polyimide resin, or the like.

The light emission layer 130 can be disposed on the first electrode 120. The light emission layer 130 can include a hole transporting layer, an emission material layer, and an electron transporting layer. In this example, when a voltage is applied to the first electrode 120 and the second electrode 140, holes and electrons migrate to the light emission layer through the hole transporting layer and the electron transporting layer, respectively, and combine with each other in the light emission layer to emit light.

The light emission layer 130 can be a common layer disposed common to the sub-pixels SP1, SP2, SP3, and SP4. In this example, the light emission layer can be a white light emission layer that emits white light. The light emission layer 130 can be disposed in the transmissive area TA as well as in the non-transmissive area NTA.

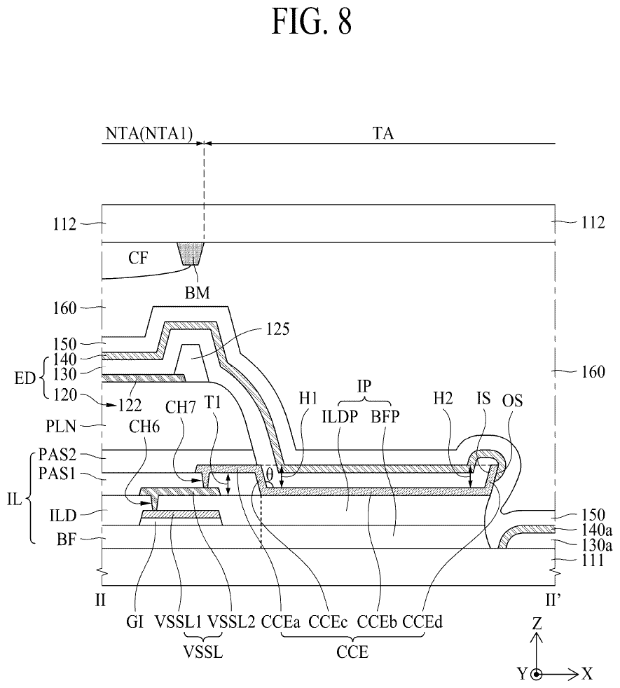

The second electrode 140 can be provided on the light emission layer 130. The second electrode 140 can be provided in the transmissive area TA as well as the non-transmissive area NTA including the emission area EA. For example, the second electrode 140 of the light emitting device ED extends from the non-transmissive area NTA to the transmissive area TA. In some embodiments, the second electrode 140 of the light emitting device ED directly contacts the at least one side portion CCEd of the cathode connection electrode CCE (see FIG. 8).

The second electrode 140 can be a common layer disposed common to the sub-pixels SP1, SP2, SP3, and SP4 to apply the same voltage. The second electrodes 140 can include a transparent conductive material TCO such as ITO, IZO, which can transmit light, or a semi-transmissive conductive material such as magnesium Mg, silver Ag, or an alloy of magnesium Mg and silver Ag. When the second electrode 140 can include a semi-transmissive conductive material, the light emission efficiency can be increased due to the micro cavity. The second electrode 140 can be the cathode electrode of a light emitting device ED.

An encapsulation layer 150 can be disposed on the light emitting device ED. The encapsulation layer 150 can be disposed to cover the second electrode 140 on the light emission layer 130. The encapsulation layer 150 can prevent oxygen or moisture from penetrating the light emission layer 130 and the second electrode 140. To this, the encapsulation layer 150 can include at least one inorganic film, and can further include at least one organic film.

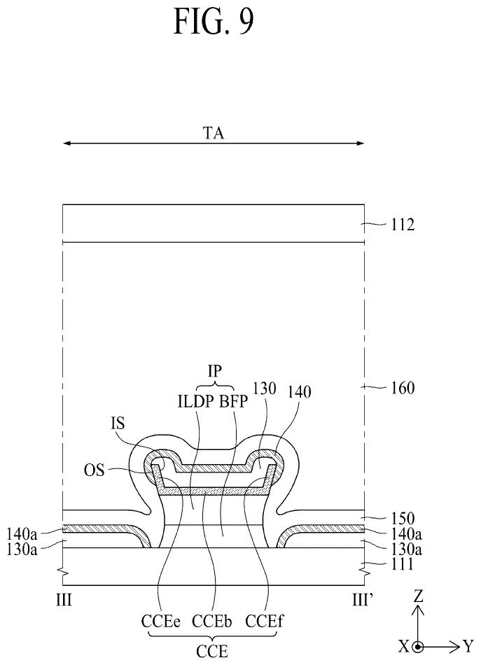

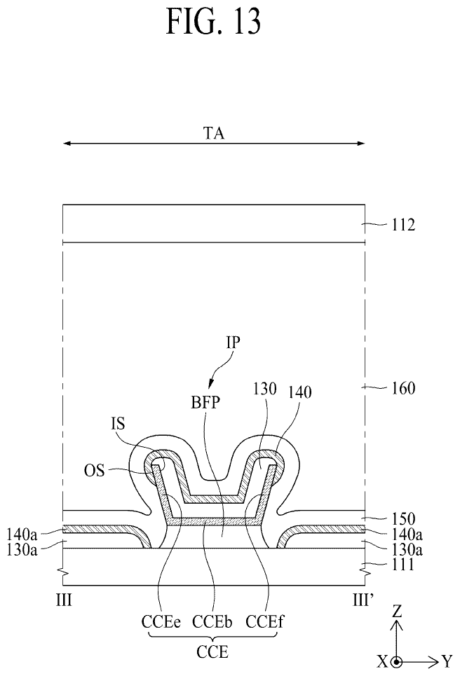

Referring to FIG. 9, the encapsulation layer 150 is disposed over an another second electrode 140a, a cathode connection electrode CCE, and an insulation layer IP. Further, in some embodiments, the encapsulation layer 150 directly contacts the another second electrode 140a, the buffer pattern BFP, the interlayer insulation pattern ILDP, the bottom portion CCEb, the at least one side portion CCEe, CCEf of the cathode connection electrode CCE, and the second electrode 140. Referring to FIG. 13, the encapsulation layer 150 is disposed over an another second electrode 140a, a cathode connection electrode CCE, and an insulation layer IP. Contrary to FIG. 9, in some embodiments, the encapsulation layer 150 directly contacts the another second electrode 140a, the buffer pattern BFP, the bottom portion CCEb, the at least one side portion CCEe, CCEf of the cathode connection electrode CCE, and the second electrode 140 but not the interlayer insulation pattern ILDP.

A color filter CF can be disposed provided on one side of the second substrate 112 facing the first substrate 111. The color filter CF can be patterned by the sub-pixels SP1, SP2, SP3, and SP4 to transmit light having a predetermined color.

Further, a black matrix BM can be disposed between the color filters CF and between the color filters CF and the transmissive area TA. The black matrix BM can be disposed between the sub-pixels SP1, SP2, SP3, and SP4 to prevent color mixing from occurring between adjacent sub-pixels SP1, SP2, SP3, and SP4, and to prevent light incident from the outside from being reflected on the plurality of signal lines disposed between the sub-pixels SP1, SP2, SP3, and SP4.

Further, the black matrix BM can be disposed between the transmissive area TA and the plurality of sub-pixels SP1, SP2, SP3, and SP4 to prevent light emitted from each of the plurality of sub-pixels SP1, SP2, SP3, and SP4 from proceeding to the transmissive area TA. The black matrix BM can include a light-absorbing material, such as a black dye that absorbs all light in the visible wavelength range.

The color filter CF and the black matrix BM described above are not disposed in the transmissive area TA to maintain a high light transmittance in the transmissive area TA.

A filler 160 can be disposed between the first substrate 111 having the light emitting device ED and the second substrate 112 having the color filter CF and the black matrix BM. In this example, the filler 160 can utilize a thermocurable resin or a UV curable resin, and can include organic material having adhesive properties. In one embodiment, the filler 160 can include a material that absorbs hydrogen.

Referring again to FIG. 4, the transparent display panel 110 according to one embodiment of the present disclosure can include a cathode connection electrode CCE contacting the second electrode 140 of the light emitting device ED in the transmissive area TA. The cathode connection electrode CCE can be connected to the common power line VSSL to supply the second power source to the second electrode 140 of the light emitting device ED. In this case, the second power source can be a common power to be supplied common to the sub-pixels SP1, SP2, SP3, and SP4.

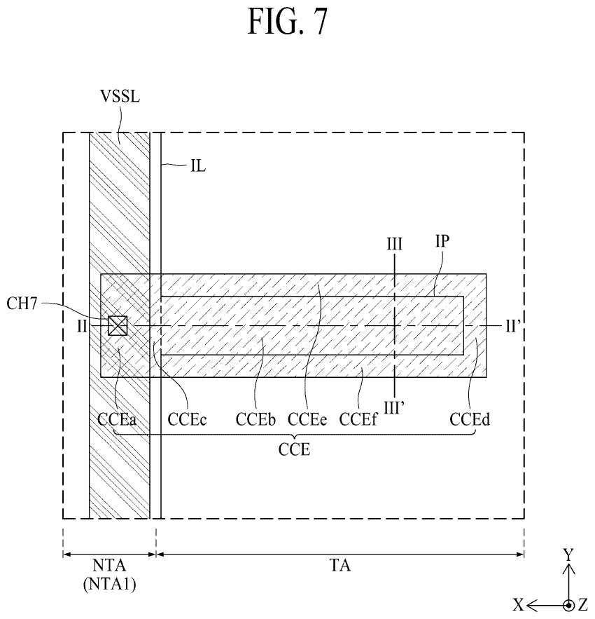

Hereinafter, the cathode connection electrode CCE will be described in more detail with reference to FIGS. 7 to 21.

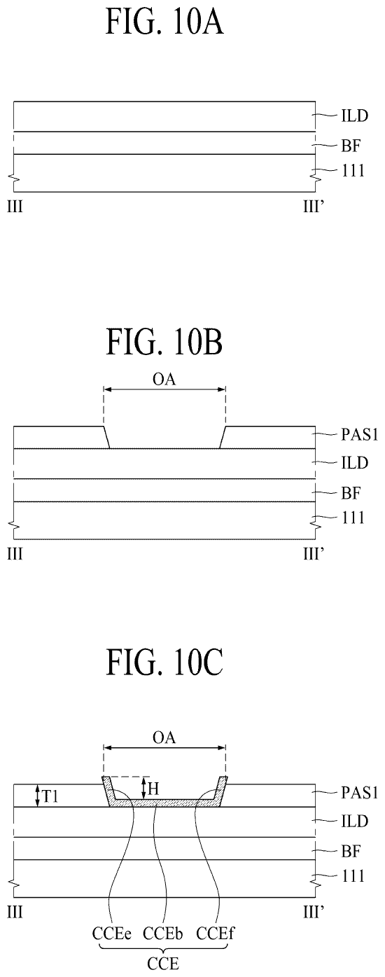

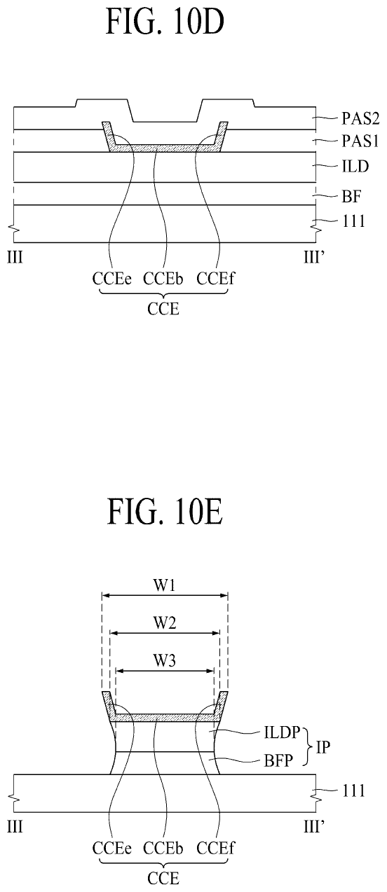

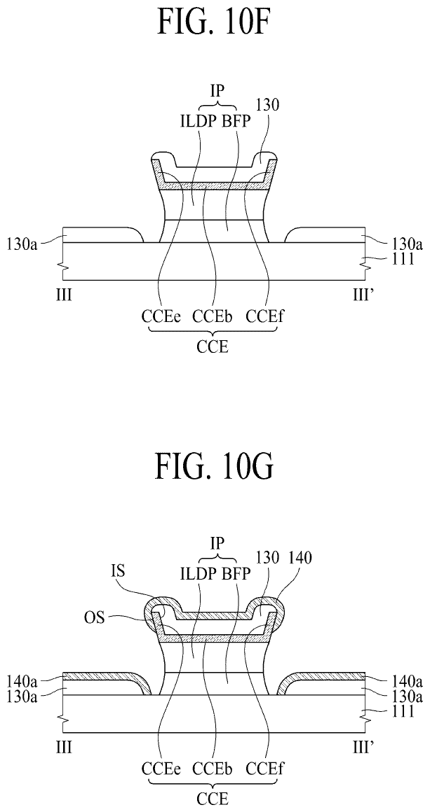

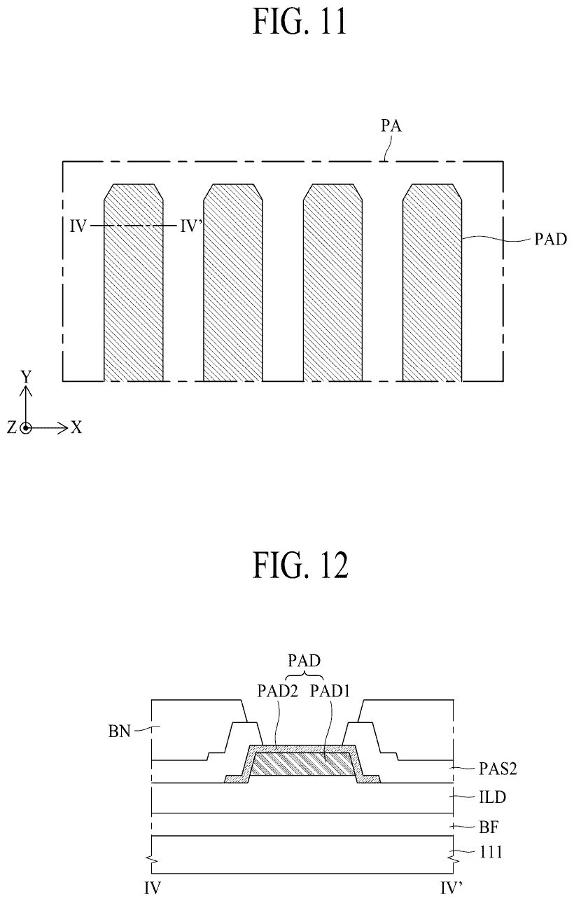

FIG. 7 is an enlarged plan view of one embodiment of a common power line and cathode connection electrode, FIG. 8 is a cross-sectional view illustrating one embodiment of II-II′ illustrated in FIG. 7, and FIG. 9 is a cross-sectional view illustrating one embodiment of III-III′ illustrated in FIG. 7. FIGS. 10A to 10G illustrates one example of a method of forming the cathode connection electrode illustrated in FIG. 9. FIG. 11 is an enlarged plan view of one example of a plurality of pads disposed in a pad area, and FIG. 12 is a cross-sectional view illustrating one embodiment of IV-IV′ illustrated in FIG. 11.

Referring to FIGS. 4, 7, 8, and 9, the cathode connection electrode CCE can electrically connect the common power line VSSL and the second electrode 140 of the light emitting device ED.

First, the common power line VSSL can be extended in the first direction (e.g., in the Y-axis direction) in the non-transmissive area NTA. Specifically, the common power line VSSL can be disposed within the first non-transmissive area NTA1 extended in the first direction (e.g., the Y-axis direction) in the display area DA. As such, the common power line VSSL overlaps with the first non-transmissive area NTA1 from a plan view (see FIG. 7). In one embodiment, the common power line VSSL can be disposed close to an edge of the first non-transmissive area NTA1. That is, the common power line VSSL can be disposed close to the transmissive area TA to minimize a distance from the cathode connection electrode CCE.

The common power line VSSL can include a plurality of metal layers. The common power line VSSL can include the first metal layer VSSL1 and the second metal layer VSSL2. The first metal layer VSSL1 can be disposed on the first substrate 111 and can be extended in the first direction (e.g., the Y-axis direction) in the first non-transmissive area NTA1.

The second metal layer VSSL2 can be disposed on the first metal layer VSSL1. The second metal layer VSSL2 can be patterned to overlap at least a portion of the first metal layer VSSL1. The interlayer insulation layer ILD can be disposed between the first metal layer VSSL1 and the second metal layer VSSL2. The second metal layer VSSL2 can be electrically connected to the first metal layer VSSL1 via the sixth contact hole CH6 penetrating the interlayer insulation layer ILD disposed between the first metal layer VSSL1 and the second metal layer VSSL2. In this example, a plurality of the sixth contact hole CH6 can be provided the second metal layer VSSL2 can be connected to the first metal layer VSSL1 through the plurality of sixth contact holes CH6, and thus, the second metal layer VSSL2 can be stably connected to the first metal layer VSSL1.

In some embodiments, the second metal layer VSSL2 is on a same layer as the bottom portion CCEb of the cathode connection electrode CCE. The first metal layer VSSL1, on the other hand, is spaced apart from the bottom portion CCEb, the connection portion CCEa, the at least one side portion CCEc of the cathode connection electrode CCE (see FIG. 8).

In one embodiment, the first metal layer VSSL1 can be formed of the same materials on the same layer as the gate electrode GE of the driving transistor (DTR), and the second metal layer VSSL2 can be formed of the same materials in the same layer as the source electrode SE and the drain electrode DE of the driving transistor DTR.

The cathode connection electrode CCE can be electrically connected to the common power line VSSL and the second electrode 140 of the light emitting device ED. Specifically, the cathode connection electrode CCE can be electrically connected to the common power line VSSL in the non-transmissive area NTA. As shown in FIG. 7, the cathode connection electrode CCE overlaps both the transmissive area TA and the first non-transmissive area NTA1 from a plan view. Here, the cathode connection electrode CCE extends from the transmissive area TA to the non-transmissive area NTA and overlaps with the common power line VSSL from a plan view.

The cathode connection electrode CCE can be disposed on a different layer than the common power line VSSL. For example, the cathode connection electrode CE can be formed of the same material on the same layer as the anode connection electrode ACE. The cathode connection electrode CCE can include the same transparent conductive material as the anode connection electrode ACE. In one example, the cathode connection electrode CCE can be one of ITO and IZO, but it is not necessarily limited thereto.

When the cathode connection electrode CCE is disposed on the same layer as the anode connection electrode ACE, the cathode connection electrode CCE can be disposed on the first insulation layer PAS1 in the non-transmissive area NTA. As shown in FIG. 8, the cathode connection electrode CCE can be electrically connected to the common power line VSSL via a seventh contact hole CH7 penetrating the first insulation layer PAS1.

The cathode connection electrode CCE can be extended in the second direction (e.g., the X-axis direction) toward the transmissive area TA, and can be electrically connected to the second electrode 140 of the light emitting device ED in the transmissive area TA. At least one side of the cathode connection electrode CCE can be electrically connected to the second electrode 140 of the light emitting device ED.

Specifically, the cathode connection electrode CCE can be disposed on at least one insulation layer IL and IP to be extended from the non-transmissive area NTA to the transmissive area TA. The number of insulation layers IL disposed below the cathode connection electrode CCE in the non-transmissive area NTA and the number of insulation layers IP disposed below the cathode connection electrode CCE in the transmissive area TA can be different. The number of insulation layers IP disposed below the cathode connection electrode CCE in the transmissive area TA can be less than the number of insulation layers IL disposed below the cathode connection electrode CCE in the non-transmissive area NTA. In one example, as shown in FIG. 8, the insulation layer IL including the buffer layer BF, the interlayer insulation layer ILD, and the first insulation layer PAS1 can be disposed below the cathode connection electrode CCE in the non-transmissive area NTA. On the other hand, the insulation layer IP including the buffer layer BF and the interlayer insulation layer ILD can be disposed below the cathode connection electrode CCE in the transmissive area TA.

Hereinafter, for convenience of description, it will be described that the insulation layer IL disposed below the cathode connection electrode CCE in the non-transmissive area NTA includes the buffer layer BF, the interlayer insulation layer ILD, and the first insulation layer PAS1, and that the insulation layer IP disposed below the cathode connection electrode CCE in the transmissive area TA includes the buffer layer BF and the interlayer insulation layer ILD. However, the number of insulation layers IP disposed below the cathode connection electrode CCE in the transmissive area TA should be less than the number of insulation layers IL disposed below the cathode connection electrode CCE in the non-transmissive area NTA, and is not necessarily limited thereto.

Since the number of insulation layers IP disposed below the cathode connection electrode CCE in the transmissive area TA can be less than the number of insulation layers IL disposed below the cathode connection electrode CCE in the non-transmissive area NTA, the cathode connection electrode CCE cannot be formed flat and can have a concave shape toward the first substrate 111.

The cathode connection electrode CCE can include a connection portion CCEa, a bottom portion CCEb, and at least one side portion CCEc, CCEd, CCEe, and CCEf extended from the bottom portion CCEb.

The connection portion CCEa of the cathode connection electrode CCE is disposed on the plurality of insulation layers ILs in the non-transmissive area NTA, and can be connected to the common power line VSSL via the seventh contact hole CH7 penetrating a portion of the plurality of insulation layers IL. As shown in FIG. 8, the connection portion CCEa of the cathode connection electrode CCE overlaps with the common power line VSSL from a plan view. The connection portion CCEa of the cathode connection electrode CCE can be connected to the common power line VSSL via the seventh contact hole CH7 penetrating the first insulation layer PAS1 of the plurality of insulation layers IL.

The bottom portion CCEb of the cathode connection electrode CCE can be disposed on the at least one insulation layer IP in the transmissive area TA. The bottom portion CCEb of the cathode connection electrode CCE can be disposed to have a height lower than that of the connection portion CCEa, and can have a flat surface. In this example, the height can represent a vertical separation distance from the first substrate 111. The bottom portion CCEb of the cathode connection electrode CCE can be flatly disposed on the upper surface of the interlayer insulation layer ILDP in the transmissive area TA.

The at least one side portion CCEc, CCEd, CCEe, and CCEf of the cathode connection electrode CCE can be disposed in the transmissive area TA. The at least one side portion CCEc, CCEd, CCEe, and CCEf of the cathode connection electrode CCE can be extended perpendicularly or outwardly inclined from the bottom portion CCEb in the transmissive area TA. The at least one side portion CCEc, CCEd, CCEe, and CCEf of the cathode connection electrode CCE can be extended toward the second substrate 112. The cathode connection electrode CCE can include at least one of a first side portion CCEc connecting the connection portion CCEa and the bottom portion CCEb, a second side portion CCEd facing the first side portion CCEc, and a third side portion CCEe and a fourth side portion CCEf connecting the first side portion CCEc and the second side portion CCEd. The connection portion CCEa, the bottom portion CCEb, and the at least one side portion CCEc, CCEd are continuously and contiguously connected to each other (see FIG. 8). For example, the connection portion CCEa extends from the at least one side portion CCEc, the at least one side portion CCEc extends from the bottom portion CCEb, and the bottom portion CCEb extends from the at least one side portion CCEd opposite of the at least one side portion CCEc.

The first side portion CCEc of the cathode connection electrode CCE can be extended along a side surface of the first insulation layer PAS1. Accordingly, an outer side surface OS of the first side portion CCEc of the cathode connection electrode CCE can contact with the side surface of the first insulation layer PAS1. The first side portion CCEc of the cathode connection electrode CCE can have a perpendicular height H1 corresponding to a thickness T1 of the first insulation layer PAS1.

Since the first insulation layer PAS1 is not disposed in the transmissive area TA, an outer side surface OS of each of the second side portion CCEd, the third side portion CCEe, and the fourth side portion CCEf of the cathode connection electrode CCE can be exposed without contacting the side surface of the first insulation layer PAS1. The second side portion CCEd, the third side portion CCEe, and the fourth side portion CCEf of the cathode connection electrode CCE do not contact the side surface of the first insulation layer PAS1, but can have a perpendicular height H2 corresponding to a thickness T1 of the first insulation layer PAS1, such as the first side portion CCEc.

The cathode connection electrode CCE can be formed to have a shape as described above by forming an opening area in the first insulation layer PAS2. First, as shown in FIG. 10A, the buffer layer BF and the interlayer insulation layer ILD can be disposed on the first substrate 111. At this time, the buffer layer BF and the interlayer insulation layer ILD can be disposed to cover the entire transmissive area TA as well as the non-transmissive area NTA.

Next, as shown in FIG. 10B, the first insulation layer PAS1 can be disposed on the interlayer insulation layer ILD. The first insulation layer PAS1 can be disposed to have an opening area OA in the transmissive area TA. A photoresist pattern can be disposed on the first insulation layer PAS1 so that an area to be the opening area OA is exposed, and an etching process can be performed. The first insulation layer PAS1 can be removed in an area not covered by the photoresist pattern so that the opening area OA can be formed.

Next, as shown in FIG. 10C, the cathode connection electrode CCE can be disposed on the first insulation layer PAS1 and the interlayer insulation layer ILD. The cathode connection electrode CCE can be patterned in an area overlapping an opening area OA of the first insulation layer PAS1. The cathode connection electrode CCE can have the bottom portion CCEb formed on an upper surface of the interlayer insulation layer ILD exposed in the opening area OA of the first insulation layer PAS1. Further, the cathode connection electrode CCE can have at least one side portion CCEc, CCEd, CCEe, and CCEf formed on a side surface of the first insulation layer PAS1 exposed in the opening area OA of the first insulation layer PAS1. The at least one side portion CCEc, CCEd, CCEe, and CCEf can be formed to have a perpendicular height H corresponding to a thickness T1 of the first insulation layer PAS1.

Next, as shown in FIG. 10D, the second insulation layer PAS2 can be disposed on the cathode connection electrode CCE and the first insulation layer PAS1.

Next, as shown in FIG. 10E, the second insulation layer PAS2, the first insulation layer PAS1, a portion of the interlayer insulation layer ILD, and a portion of the buffer layer BF can be etched by a wet etch process. The high concentration wet etch process can leave the second insulation layer PAS2, the first insulation layer PAS1, a portion of the interlayer insulation layer ILD, and a portion of the buffer layer BF in the non-transmissive area NTA, and can remove them from the transmissive area TA. In an area where the second insulation layer PAS2, the first insulation layer PAS1, a portion of the interlayer insulation layer ILD, and a portion of the buffer layer BF are removed, the first substrate 111 can be exposed.

However, since the cathode connection electrode CCE blocks the etchant, a portion of the interlayer insulation layer ILD and the buffer layer BF disposed below the cathode connection electrode CCE can be left in a pattern form without being etched. Accordingly, the insulation pattern IP including the interlayer insulation pattern ILDP and the buffer pattern BFP can be provided below the cathode connection electrode CCE.

Since the wet etch process is isotropically etched due to its characteristics, the cathode connection electrode CCE and the insulation pattern IP can have an undercut structure. That is, a width W3 of at least a portion of the insulation pattern IP can be smaller than the width W1 of the cathode connection electrode CCE. At least one side portion CCEe and CCEf of the cathode connection electrode CCE can be formed to be inclined outwardly from the bottom portion CCEb. Accordingly, the bottom portion CCEb of the cathode connection electrode CCE can have a width W2 less than the entire width W1 of the cathode connection electrode CCE. The width W3 of at least a portion of the insulation pattern IP can be smaller than the width W2 of the bottom portion CCEb of the cathode connection electrode CCE. The widths W1, W2, and W3 can be a length in the first direction (e.g., the Y-axis direction), but are not necessarily limited thereto. The widths W1, W2, and W3 can be a length in the second direction (e.g., the X-axis direction).

The insulation pattern IP can overlap the cathode connection electrode CCE and can be disposed along the cathode connection electrode CCE. The insulation pattern IP can have the same shape as the cathode connection electrode CCE on the plane in the transmissive area TA, and can have a smaller size than the cathode connection electrode CCE.

Next, as shown in FIG. 10F, the light emission layer 130 of the light emitting device ED can be disposed on the cathode connection electrode CCE. The light emission layer 130 can be disconnected by the cathode connection electrode CCE in the transmissive area TA. The light emission layer 130 can be a common layer disposed in common to the sub-pixels SP1, SP2, SP3, and SP4. The light emission layer 130 can be disposed in the transmissive area TA as well as in the non-transmissive area NTA.

The light emission layer 130 can be disconnected by at least one side portion CCEe and CCEf of the cathode connection electrode CCE protruded toward the second substrate 112 in the transmissive area TA. Some of the light emission layers 130 can be disposed to contact the bottom portion CCEb of the cathode connection electrode CCE and the inner side surface IS of each of the side portions CCEe and CCEf of the cathode connection electrode CCE. Another part of the light emission layer 130a can be disposed to be disconnected from the light emission layer 130 disposed on the cathode connection electrode CCE without being continuous and thus, another part of the light emission layer 130a can contact the upper surface of the exposed first substrate 111. In this example, the outer side surface OS of the side portions CCEe and CCEf of the cathode connection electrode CCE can be exposed without being covered by the light emission layer 130.

Next, as shown in FIG. 10G, the second electrode 140 of the light emitting device ED can be disposed on the light emission layer 130. The second electrode 140 can be disconnected by the cathode connection electrode CCE in the transmissive area TA. The second electrode 140 can be a common layer disposed in common to the sub-pixels SP1, SP2, SP3, and SP4. The second electrode 140 can be disposed in the transmissive area TA as well as in the non-transmissive area NTA.

These second electrode 140 can be disconnected by at least one side portion CCEe and CCEf of the cathode connection electrode CCE and the insulation pattern IP, at least one side portion CCEe and CCEf of the cathode connection electrode CCE can be protruded toward the second substrate 112 in the transmissive area TA. A portion of the second electrode 140 can be disposed to cover the light emission layer 130 on the light emission layer 130 disposed in the cathode connection electrode CCE. The second electrode 140 can have a better step coverage than the light emission layer 130 including organic material, and thus can be deposited to have a larger area than that of the light emission layer 130. Accordingly, the portion of the second electrode 140 can be disposed on the outer side surface OS of the side portions CCEe and CCEf of the cathode connection electrode CCE that are not covered by the light emission layer 130 and are exposed. The at least a portion of the outer side surface OS of the side portions CCEe and CCEf of the cathode connection electrode CCE can contact the second electrode 140 of the light emitting device ED.

Meanwhile, another second electrode 140a can be disposed to be disconnected from the second electrode 140 disposed on the cathode connection electrode CCE without being continuous, and thus another second electrode 140a can contact the light emission layer 130a disposed on the upper surface of the exposed first substrate 111.

Referring again to FIGS. 7 to 9, an one end of the cathode connection electrode CCE can be electrically connected to the common power line VSSL, and the outer side surface OS of at least one of the side portions CCEd, CCEe, and CCEf of the cathode connection electrode CCE can be electrically connected to the second electrode 140 of the light emitting device ED. As a result, the second electrode 140 of the light emitting device ED can be supplied with the second power from the common power line VSSL through the cathode connection electrode CCE.

The transparent display panel 110 according to one embodiment of the present disclosure can electrically connect the second electrode 140 of the light emitting device ED and the common power line VSSL using the cathode connection electrode CCE. In the transparent display panel 110 according to one embodiment of the present disclosure, the cathode connection electrode CCE can include a transparent conductive material. Thereby, in the transparent display panel 110 according to one embodiment of the present disclosure, even though the cathode connection electrode CCE is disposed in the transmissive area TA, there can be no decrease in the light transmittance of the transmissive area TA due to the cathode connection electrode CCE.

Moreover, when an opaque metal line is disposed in the transmissive area TA, external light passing through the transmissive area TA can be diffracted by the opaque metal line. In the transparent display panel 110 according to one embodiment of the present disclosure, since the cathode connection electrode CCE disposed in the transmissive area TA can be formed as a transparent conductive line, diffraction from occurring in the external light passing through the transmissive area TA can be prevented.

Moreover, in the transparent display panel 110 according to one embodiment of the present disclosure, the cathode connection electrode CCE can have at least one side portion CCEd, CCEe, and CCEf, and the second electrode 140 of the light emitting device ED can be contacted on the outer side surface OS of the at least one side portion CCEd, CCEe, and CCEf. In the transparent display panel 110 according to one embodiment of the present disclosure, a contact area between the cathode connection electrode CCE and the second electrode 140 of the light emitting device ED can be increased. Thereby, in the transparent display panel 110 according to one embodiment of the present disclosure, the cathode connection electrode CCE and the second electrode 140 of the light emitting device ED can stably contact.

Moreover, the transparent display panel 110 according to one embodiment of the present disclosure can increase transparency by removing the first insulation layer PAS1, the second insulation layer PAS2, and the planarization layer PLN in the transmissive area TA. Furthermore, in the transparent display panel 110 according to one embodiment of the present disclosure, since a portion of each of the buffer layer BF and the interlayer insulation layer ILD can be removed in the transmissive area TA and is disposed only in a minimum area of the transmissive area TA, transparency can be further increased.

Moreover, in the transparent display panel 110 according to one embodiment of the present disclosure, an organic insulation layer, such as the planarization layer PLN cannot be disposed around the cathode connection electrode CCE in the transmissive area TA, but only an inorganic insulation layer can be disposed. Thereby, the transparent display panel 110 according to one embodiment of the present disclosure can prevent moisture from penetrating the cathode connection electrode CCE through the planarization layer PLN. The transparent display panel 110 according to one embodiment of the present disclosure can extend the lifespan of the display device, and as the lifespan of the display device increases, the manufacturing process for producing a new display device can be reduced, thereby reducing the generation of greenhouse gases due to the manufacturing process and implementing ESG (Environment/Social/Governance).

Moreover, in the transparent display panel 110 according to one embodiment of the present disclosure, since the planarization layer PLN cannot be disposed in the transmissive area TA, it is not necessary to dispose the cathode connection electrode CCE long in the longitudinal direction to separate the cathode connection electrode CCE from the planarization layer PLN. In the transparent display panel 110 according to one embodiment of the present disclosure, the cathode connection electrode CCE can be disposed short in the longitudinal direction. That is, the transparent display panel 110 according to one embodiment of the present disclosure can reduce a distance between the end of the cathode connection electrode CCE and the non-transmissive area NTA.

Moreover, in the transparent display panel 110 according to one embodiment of the present disclosure, the cathode connection electrode CCE can be simultaneously formed on the same layer as the anode connection electrode ACE. In the transparent display panel 110 according to one embodiment of the present disclosure, the cathode connection electrode CCE can be formed through a simple process. Accordingly, in the transparent display panel 110 according to one embodiment of the present disclosure, process optimization can be implemented and production energy can be reduced.

Moreover, in the transparent display panel 110 according to one embodiment of the present disclosure, the cathode connection electrode CCE can be simultaneously formed on the same layer as the pads PADs of the pad area PA. Specifically, as shown in FIG. 11, a plurality of pads PAD can be disposed in the pad area PA. The plurality of pads PAD can be extend in the second direction (e.g., the Y-axis direction) and spaced apart from each other in the first direction (e.g., the X-axis direction). Each of the plurality of pads PAD can be connected to at least one of the plurality of signal lines provided in the display area DA. Each of the plurality of signal lines can be extended from the display area DA to the non-display area NDA, and can be electrically connected to any one of the plurality of pads PAD disposed in the pad area PA.

As shown in FIG. 12, each of the plurality of pads PAD can include a signal pad PAD1 and a pad electrode PAD2.

The signal pad PAD1 can be disposed in the pad area PA on the first substrate 111. In one embodiment, the signal pad PAD1 can be disposed on the buffer layer BF and the interlayer insulation layer ILD. The buffer layer BF and the interlayer insulation layer ILD can be extended to the display area DA as well as to the non-display area NDA including the pad area PA. The buffer layer BF and the interlayer insulation layer ILD disposed in the pad area PA can block moisture or impurities penetrating through the first substrate 111 from moving to the signal pad PAD1.

The signal pad electrode PAD1 can be formed of the same material on the same layer as the source electrode SE and the drain electrode DE of the driving transistor DTR but is not necessarily limited thereto. The signal pad PAD1 can be formed of the same material on the same layer as the gate electrode GE of the driving transistor DTR. The signal pad PAD1 can be formed as a single layer or multiple layers of any one of molybdenum Mo, aluminum Al, chromium Cr, gold Au, titanium Ti, nickel Ni, neodymium Nd, and copper Cu, or an alloy thereof.

The pad electrode PAD2 can be disposed to cover the signal pad PAD1 on the signal pad PAD1. The pad electrode PAD2 can be electrically connected to the signal pad PAD1 by contacting an upper surface of the signal pad PAD1. The second insulation layer PAS2 and the bank BN can be disposed on the pad electrode PAD2. The second insulation layer PAS2 and the bank BN disposed on the pad electrode PAD2 can include an opening area. The opening area can be formed by removing a portion of the second insulation PAS2 and the bank BN through an etching process to expose a portion of the upper surface of the pad electrode PAD2.

The pad electrode PAD2 can be formed of the same material in the same layer as the cathode connection electrode CCE provided in the display area DA. The pad electrode PAD2 can include a transparent conductive material, such as any one of ITO and IZO. The cathode connection electrode CCE can be formed in the pad area PA by the same process as the pad electrode PAD2. In the transparent display panel 110 according to one embodiment of the present disclosure, process optimization can be implemented, thereby reducing production energy.

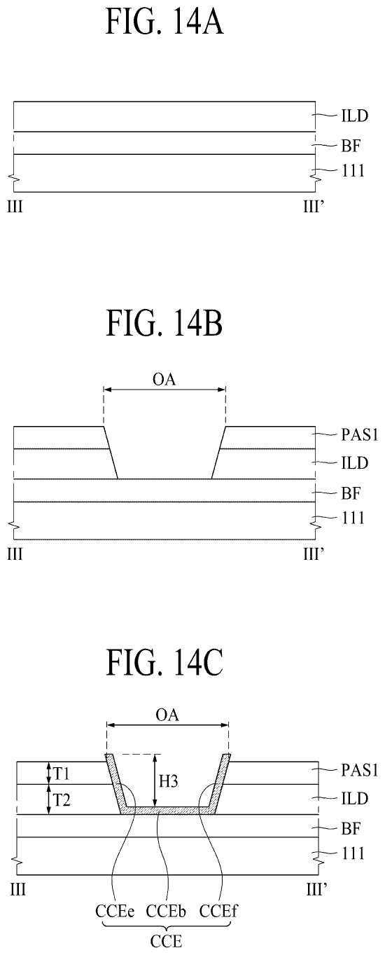

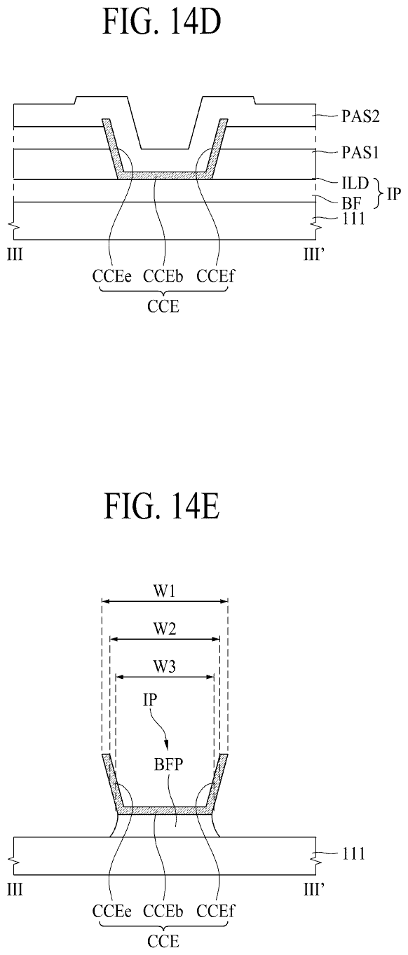

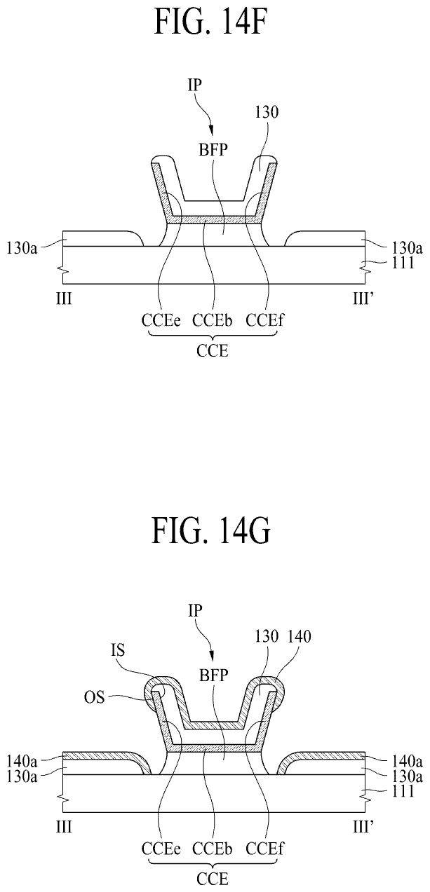

FIG. 13 is a cross-sectional view illustrating another embodiment of III-III′ illustrated in FIG. 7, and FIGS. 14A to 14G illustrates one example of a method of forming the cathode connection electrode illustrated in FIG. 13.

The cathode connection electrode CCE illustrated in FIGS. 8 and 9 has been described as having the side portions CCEc, CCEd, CCEe, and CCEf having the perpendicular height H corresponding to a thickness T1 of the first insulation layer PAS1, but is not necessarily limited thereto. The side portions CCEc, CCEd, CCEe, and CCEf of the cathode connection electrode CCE can also have the perpendicular height H greater than the thickness T1 of the first insulation layer PAS1. Hereinafter, differences between the cathode connection electrode CCE illustrated in FIG. 13 and the cathode connection electrode CCE illustrated in FIGS. 8 and 9 will be described in detail, and substantially identical content can be omitted.

Referring to FIGS. 7 and 13, the cathode connection electrode CCE can be disposed on at least one insulation layer IL and IP to be extended toward the transmissive area TA in the non-transmissive area NTA. The number of insulation layers IL disposed below the cathode connection electrode CCE in the non-transmissive area NTA and the number of insulation layers IP disposed below the cathode connection electrode CCE in the transmissive area TA can be different. The number of insulation layers IP disposed below the cathode connection electrode CCE in the transmissive area TA can be less than the number of insulation layers IL disposed below the cathode connection electrode CCE in the non-transmissive area NTA. In one example, as shown in FIG. 8, the insulation layer IL including the buffer layer BF, the interlayer insulation layer ILD, and the first insulation layer PAS1 can be disposed below the cathode connection electrode CCE in the non-transmissive area NTA. On the other hand, as shown in FIG. 13, the insulation layer IP including the buffer layer BF can be disposed below the cathode connection electrode CCE in the transmissive area TA.

Since the number of insulation layers IP disposed below the cathode connection electrode CCE in the transmissive area TA can be less than the number of insulation layers IL disposed below the cathode connection electrode CCE in the non-transmissive area NTA, the cathode connection electrode CCE cannot be formed flat and can have a concave shape toward the first substrate 111.

The cathode connection electrode CCE can include the connection portion CCEa, the bottom portion CCEb, and at least one side portion CCEc, CCEd, CCEe, and CCEf extended from the bottom portion CCEb.

The connection portion CCEa of the cathode connection electrode CCE is connected to the common power line VSSL via the seventh contact hole CH7 penetrating the first insulation layer PAS1 of the plurality of insulation layers IL. The bottom portion CCEb of the cathode connection electrode CCE can be disposed to have a height lower than that of the connection portion CCEa, and can be flatly disposed on the upper surface of the buffer layer BFP in the transmissive area TA.

The at least one side portion CCEc, CCEd, CCEe, and CCEf of the cathode connection electrode CCE can be extended perpendicularly or outwardly inclined from the bottom portion CCEb in the transmissive area TA. For example, as shown in FIG. 8, the at least one side portion CCEa or CCEd is inclined relative to the bottom portion CCEb at an inclination angle θ. The inclination angle θ can be 90° (i.e., perpendicular) or can have an angle greater than 90° such that the at least one side portion CCEc, CCEd, CCEe, and CCEf of the cathode connection electrode CCE can be extending outwardly. The at least one side portion CCEc, CCEd, CCEe, and CCEf of the cathode connection electrode CCE can be extended toward the second substrate 112.

The cathode connection electrode CCE can include at least one of the first side portion CCEc connecting the connection portion CCEa and the bottom portion CCEb, the second side portion CCEd facing the first side portion CCEc, and the third side portion CCEe and the fourth side portion CCEf connecting the first side portion CCEc and the second side portion CCEd. The first side portion CCEc of the cathode connection electrode CCE can be extended along a side surface of the interlayer insulation layer ILD and the first insulation layer PAS1. Accordingly, an outer side surface OS of the first side portion CCEc of the cathode connection electrode CCE can contact a side surface of each of the interlayer insulation layer ILD and the first insulation layer PAS1. The first side portion CCEc of the cathode connection electrode CCE can have the perpendicular height H3 corresponding to a sum of a thickness T1 of the first insulation layer PAS1 and a thickness T2 of the interlayer insulation layer ILD.

Since the first insulation layer PAS1 and the interlayer insulation layer ILD are not disposed in the transmissive area TA, an outer side surface OS of each of the second side portion CCEd, the third side portion CCEe, and the fourth side portion CCEf of the cathode connection electrode CCE can be exposed without contacting the side of the first insulation layer PAS1 and the side of the interlayer insulation layer ILD. The second side portion CCEd, the third side portion CCEe, and the fourth side portion CCEf of the cathode connection electrode CCE do not contact the side surface of the first insulation layer PAS1 and the side surface of the interlayer insulation layer ILD, but can have the perpendicular height H3 corresponding to a sum of the thickness T1 of the first insulation layer PAS1 and the thickness T2 of the interlayer insulation layer ILD, such as the first side portion CCEc.

The cathode connection electrode CCE can be formed to have a shape as described above by forming an opening area in the first insulation layer PAS1 and the interlayer insulation layer ILD. First, as shown in FIG. 14A, the buffer layer BF can be disposed on the first substrate 111. In this example, the buffer layer BF can be disposed to cover the entire transmissive area TA as well as the non-transmissive area NTA.

Next, as shown in FIG. 14B, the first insulation layer PAS1 and the interlayer insulation layer ILD can be disposed on the buffer layer BF. Each of the first insulation layer PAS1 and the interlayer insulation layer ILD can be disposed to have an opening area OA within the transmissive area TA. A photoresist pattern can be disposed on the first insulation layer PAS1 that an area to be the opening area OA is exposed, and an etching process can be performed on each of the first insulation layer PAS1 and the interlayer insulation layer ILD. Each of the first insulation layer PAS1 and the interlayer insulation layer ILD can be removed in an area not covered by the photoresist pattern, that the opening area OA can be formed.

Next, as shown in FIG. 14C, the cathode connection electrode CCE can be disposed on the first insulation layer PAS1, the interlayer insulation layer ILD, and the buffer layer BF. The cathode connection electrode CCE can be patterned in an area overlapping the opening area OA of the first insulation layer PAS1 and the interlayer insulation layer ILD. The cathode connection electrode CCE can have the bottom portion CCEb formed on an upper surface of the buffer layer BF exposed in the opening area OA of the first insulation layer PAS1 and the interlayer insulation layer ILD. Further, the cathode connection electrode CCE can have at least one side portion CCEc, CCEd, CCEe, and CCEf formed on a side surface of the first insulation layer PAS1 and on a side surface of the interlayer insulation layer ILD, which are exposed in the opening area OA. The at least one side portion CCEc, CCEd, CCEe, and CCEf can have the perpendicular height H3 corresponding to a sum of the thickness T1 of the first insulation layer PAS1 and the thickness T2 of the interlayer insulation layer ILD.

Next, as shown in FIG. 14D, the second insulation layer PAS2 can be disposed on the cathode connection electrode CCE and the first insulation layer PAS1.

Next, as shown in FIG. 14E, a portion of the second insulation layer PAS2, the first insulation layer PAS1, the interlayer insulation layer ILD, and the buffer layer BF can be etched through a wet etching process. The high concentration wet etching process can leave a portion of the second insulation layer PAS2, the first insulation layer PAS1, the interlayer insulation layer ILD, and the buffer layer BF in the non-transmissive area NTA, and can remove them from the transmissive area TA. In an area where a portion of the second insulation layer PAS2, the first insulation layer PAS1, the interlayer insulation layer ILD, and the buffer layer BF are removed, the first substrate 111 can be exposed.

However, the buffer layer BF disposed below the cathode connection electrode CCE can block the etchant, thus a portion of the buffer layer BF can be left in a pattern form without being etched. Accordingly, the insulation pattern IP including the buffer pattern BFP can be disposed below the cathode connection electrode CCE.

Since the wet etch process is isotropically etched due to its characteristics, the cathode connection electrode CCE and the insulation pattern IP can have an undercut structure. That is, a width W3 of at least a portion of the insulation pattern IP can be smaller than the width W1 of the cathode connection electrode CCE. At least one side portion CCEe and CCEf of the cathode connection electrode CCE can be formed to be inclined outwardly from the bottom portion CCEb. Accordingly, the bottom portion CCEb of the cathode connection electrode CCE can have a width W2 less than the entire width W1 of the cathode connection electrode CCE. The width W3 of at least a portion of the insulation pattern IP can be smaller than the width W2 of the bottom portion CCEb of the cathode connection electrode CCE. The widths W1, W2, and W3 can be a length in the first direction (e.g., the Y-axis direction), but are not necessarily limited thereto. The widths W1, W2, and W3 can be a length in the second direction (e.g., the X-axis direction).

The insulation pattern IP can overlap the cathode connection electrode CCE and can be disposed along the cathode connection electrode CCE. The insulation pattern IP can have the same shape as the cathode connection electrode CCE on the plane in the transmissive area TA, and can have a smaller size than the cathode connection electrode CCE.

Next, as shown in FIG. 14F, the light emission layer 130 of the light emitting device ED can be disposed on the cathode connection electrode CCE. The light emission layer 130 can be disconnected by the cathode connection electrode CCE in the transmissive area TA. The light emission layer 130 can be a common layer disposed in common to the sub-pixels SP1, SP2, SP3, and SP4. The light emission layer 130 can be disposed in the transmissive area TA as well as in the non-transmissive area NTA.

The light emission layer 130 can be disconnected by at least one side portion CCEe and CCEf of the cathode connection electrode CCE protruded toward the second substrate 112 in the transmissive area TA. Some of the light emission layers 130 can be disposed to contact the bottom portion CCEb of the cathode connection electrode CCE and the inner side surface IS of each of the side portions CCEe and CCEf of the cathode connection electrode CCE. Another part of the light emission layer 130a can be disposed to be disconnected from the light emission layer 130 disposed on the cathode connection electrode CCE without being continuous and thus, another part of the light emission layer 130a can contact the upper surface of the exposed first substrate 111. In this example, the outer side surface OS of the side portions CCEe and CCEf of the cathode connection electrode CCE can be exposed without being covered by the light emission layer 130.

Next, as shown in FIG. 14G, the second electrode 140 of the light emitting device ED can be disposed on the light emission layer 130. The second electrode 140 can be disconnected by the cathode connection electrode CCE in the transmissive area TA. The second electrode 140 can be a common layer disposed in common to the sub-pixels SP1, SP2, SP3, and SP4. The second electrode 140 can be formed in the transmissive area TA as well as in the non-transmissive area NTA.

The second electrode 140 can be disconnected by at least one side portion CCEe and CCEf of the cathode connection electrode CCE and the insulation pattern IP, at least one side portion CCEe and CCEf of the cathode connection electrode CCE and the insulation pattern IP are protruded toward the second substrate 112 in the transmissive area TA. Some of the second electrode 140 can be disposed to cover the light emission layer 130 on the light emission layer 130 disposed in the cathode connection electrode CCE. The second electrode 140 can have a better step coverage than the light emission layer 130 including organic material, and thus can be deposited to have a larger area than that of the light emission layer 130. Accordingly, the portion of the second electrode 140 can be disposed on the outer side surface OS of the side portions CCEe and CCEf of the cathode connection electrode CCE that are not covered by the light emission layer 130 and are exposed. The at least a portion of the outer side surface OS of the side portions CCEe and CCEf of the cathode connection electrode CCE can contact the second electrode 140 of the light emitting device ED.

Meanwhile, another second electrode 140a can be disposed to be disconnected from the second electrode 140 disposed on the cathode connection electrode CCE without being continuous, and thus another second electrode 140a can contact the light emission layer 130a disposed on the upper surface of the exposed first substrate 111.

Referring again to FIGS. 7 and 13, an one end of the cathode connection electrode CCE can be electrically connected to the common power line VSSL, and the outer side surface OS of at least one of the side portions CCEd, CCEe, and CCEf of the cathode connection electrode CCE can be electrically connected to the second electrode 140 of the light emitting device ED. As a result, the second electrode 140 of the light emitting device ED can be supplied with the second power from the common power line VSSL through the cathode connection electrode CCE.

In the transparent display panel 110 according to one embodiment of the present disclosure, the perpendicular height H of the at least one side portion CCEd, CCEe, and CCEf of the cathode connection electrode CCE can freely be varied. The perpendicular height H of the at least one side portion CCEd, CCEe, and CCEf of the cathode connection electrode CCE can be varied depending on the number of insulation layers forming the opening area OA during the manufacturing process. As the number of insulation layers forming the opening area OA increases, the perpendicular height H of the at least one side portion CCEd, CCEe, and CCEf of the cathode connection electrode CCE can also increase. In the transparent display panel 110 according to one embodiment of the present disclosure, by increasing the perpendicular height H of the at least one side portion CCEd, CCEe and CCEf of the cathode connection electrode CCE, contact between the second electrode 140 of the light emitting device ED and the cathode connection electrode CCE can be facilitated.

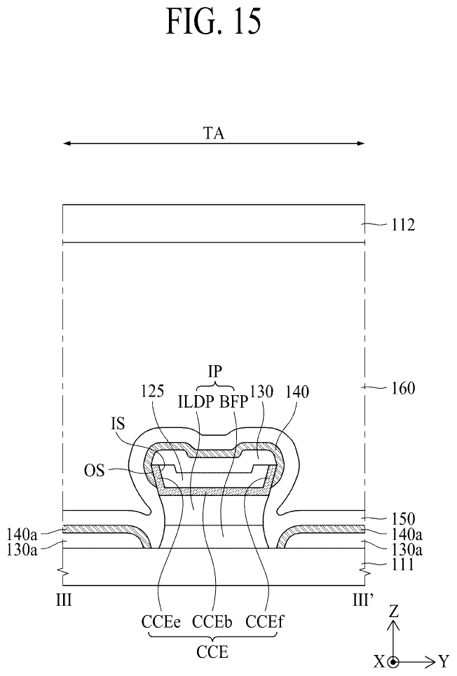

FIG. 15 is a cross-sectional view illustrating another embodiment illustrated in III-III′ of FIG. 7.

The cathode connection electrode CCE illustrated in FIGS. 8, 9, and 13 are described that the light emission layer 130 is disposed to contact the bottom portion CCEb of the cathode connection electrodes CCE and the inner side surface IS of each of the side portions CCEe and CCEf of the cathode connection electrodes CCE, but not necessarily limited to.

As shown in FIG. 15, a protection layer 125 can be further disposed on the bottom portion CCEb and the inner side surface IS of each of and the side portions CCEe and CCEf. The protection layer 125 can overlap the cathode connection electrode CCE in the transmissive area TA and can be disposed along the cathode connection electrode CCE. The protection layer 125 can have the same shape as the cathode connection electrode CCE on the plane in the transmissive area TA.

The protection layer 125 can be disposed directly on the cathode connection electrode CCE. That is, the protection layer 125 can be disposed such that the protection layer 125 directly contacts the inner side surface IS of the at least one side portion CCEe, CCEf and the bottom portion CCEb of the cathode connection electrode CCE. The protection layer 125 can be disposed to cover the inner side surface IS of the cathode connection electrode CCE, thereby preventing the etchant from seeping through the microcracks formed in the cathode connection electrode CCE.

The cathode connection electrode CCE can be formed as a single-layer of a transparent conductive material, taking into account the light transmittance of the transmissive area TA. As the cathode connection electrode CCE is formed as a thin single-layer, microscopic cracks can exist on the upper surface. In this case, during the etching process, the etchant can penetrate into the insulation layer IP disposed below the cathode connection electrode CCE through the microscopic cracks formed in the cathode connection electrode CCE. As a result, the insulation layer IP disposed below the cathode connection electrode CCE can be damaged.

The protection layer 125 can cover microscopic cracks formed in the cathode connection electrode CCE, thereby preventing the etchant from penetrating the insulation layer IP disposed below the cathode connection electrode CCE through the microscopic cracks during the etching process. The protection layer 125 can include an inorganic material, for example, the same material on the same layer as the second insulation layer PAS2.

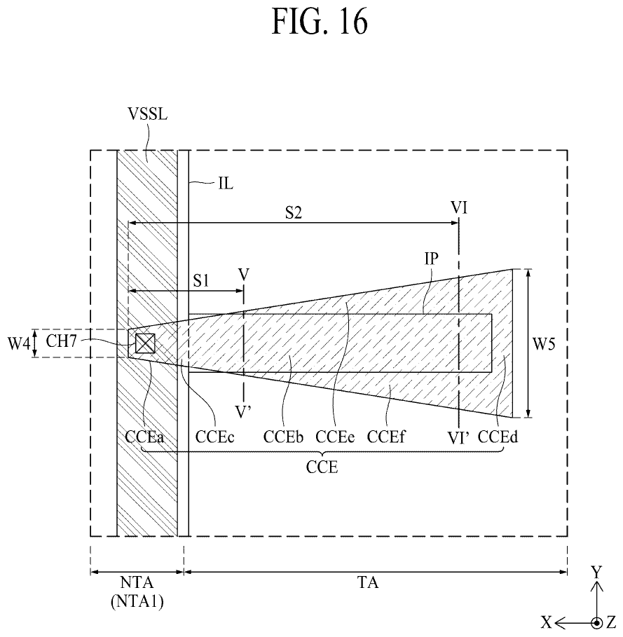

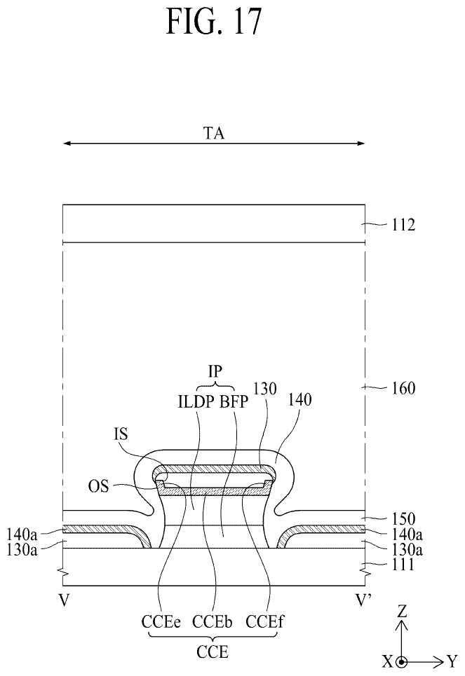

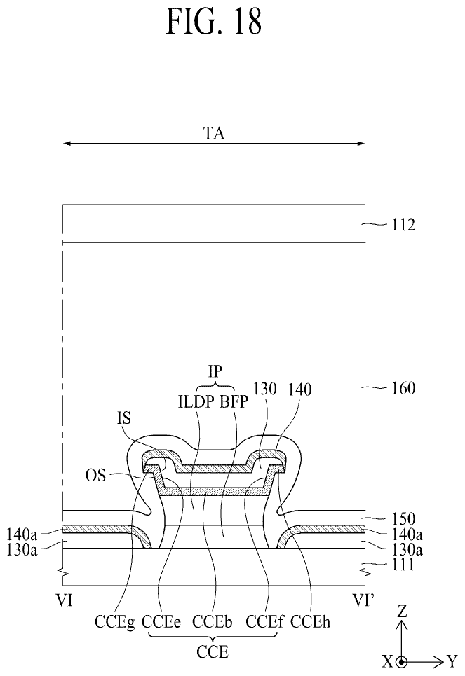

As can be seen from a cross-sectional view (sec FIGS. 9, 13, 15, 17, 18, and 21), the at least one side portion of the cathode connection electrode includes an inner side surface IS and an outer side surface OS opposite and facing the inner side surface IS. In some embodiments, the second electrode 140 of the light emitting device ED directly contacts the outer side surface OS of the at least one side portion CCEe, CCEf of the cathode connection electrode CCE and extends towards the bottom portion CCEb of the cathode connection electrode CCE. Here, the second electrode 140 of the light emitting device ED is spaced apart from the inner side surface IS of the at least one side portion of the cathode connection electrode CCE. That is, the second electrode 140 directly contacts the outer side surface OS and bends over towards the inner side surface IS but does not directly contact the inner side surface IS. Some embodiments such as FIG. 13 illustrate the flat portion of the second electrode 140 extending down towards the bottom portion CCEb more than embodiments shown in FIG. 9 or FIG. 15. FIG. 16 is an enlarged plan view of another embodiment of a common power line and cathode connection electrode, FIG. 17 is a cross-sectional view illustrating one embodiment of V-V′ illustrated in FIG. 16, and FIG. 18 is a cross-sectional view illustrating one embodiment of VI-VI′ illustrated in FIG. 16.

The cathode connection electrode CCE illustrated in FIG. 7 is described as having a certain width and extending toward the transmissive area TA in the non-transmissive area NTA, but is not necessarily limited thereto. The cathode connection electrode CCE can also have a different width depending on its location. Hereinafter, differences between the cathode connection electrode CCE illustrated in FIGS. 16 to 18 and the cathode connection electrode CCE illustrated in FIGS. 7 through 9 will be described in detail, and substantially identical content can be omitted.

Referring to FIGS. 16 to 18, the cathode connection electrode CCE can be electrically connected to the common power line VSSL and the second electrode 140 of the light emitting device ED. Specifically, the cathode connection electrode CCE can be electrically connected to the common power line VSSL via the seventh contact hole CH7 in the non-transmissive area NTA.

The cathode connection electrode CCE can be extended in the second direction (e.g., the X-axis direction) toward the transmissive area TA, and can be electrically connected to the second electrode 140 of the light emitting device ED in the transmissive area TA. At least one side of the cathode connection electrode CCE can be electrically connected to the second electrode 140 of the light emitting device ED.

Specifically, the cathode connection electrode CCE can be disposed on at least one insulation layer IL and IP to extend from the non-transmissive area NTA to the transmissive area TA. The number of insulation layers IL disposed below the cathode connection electrode CCE in the non-transmissive area NTA and the number of insulation layers IP disposed below the cathode connection electrode CCE in the transmissive area TA can be different. The number of insulation layers IP disposed below the cathode connection electrode CCE in the transmissive area TA can be less than the number of insulation layers IL disposed below the cathode connection electrode CCE in the non-transmissive area NTA. In one example, as shown in FIGS. 17 and 18, the insulation layer IL including the buffer layer BF, the interlayer insulation layer ILD, and the first insulation layer PAS1 can be disposed below the cathode connection electrode CCE in the non-transmissive area NTA. On the other hand, the insulation layer IP including the buffer layer BF and the interlayer insulation layer ILD can be disposed below the cathode connection electrode CCE in the transmissive area TA.

Hereinafter, for convenience of description, it will be described that the insulation layer IL disposed below the cathode connection electrode CCE in the non-transmissive area NTA includes the buffer layer BF, the interlayer insulation layer ILD, and the first insulation layer PAS1, and that the insulation layer IP disposed below the cathode connection electrode CCE in the transmissive area TA includes the buffer layer BF and the interlayer insulation layer ILD. However, the number of insulation layers IP disposed below the cathode connection electrode CCE in the transmissive area TA should be less than the number of insulation layers IL disposed below the cathode connection electrode CCE in the non-transmissive area NTA, and is not necessarily limited thereto.

Since the number of insulation layers IP disposed below the cathode connection electrode CCE in the transmissive area TA can be less than the number of insulation layers IL disposed below the cathode connection electrode CCE in the non-transmissive area NTA, the cathode connection electrode CCE cannot be formed flat and can have a concave shape toward the first substrate 111.

The cathode connection electrode CCE can include the connection portion CCEa, the bottom portion CCEb, and at least one side portion CCEc, CCEd, CCEe, and CCEf extending from the bottom portion CCEb.

The connection portion CCEa of the cathode connection electrode CCE is disposed on the plurality of insulation layers ILs in the non-transmissive area NTA and can be connected to the common power line VSSL through the seventh contact hole CH7 penetrating a portion of the plurality of insulation layers IL. The connection portion CCEa of the cathode connection electrode CCE can be connected to the common power line VSSL via the seventh contact hole CH7 penetrating the first insulation layer PAS1 of the plurality of insulation layers IL.

The bottom portion CCEb of the cathode connection electrode CCE can be disposed on the at least one insulation layer IP in the transmissive area TA. The bottom portion CCEb of the cathode connection electrode CCE can be disposed to have a height lower than that of the connection portion CCEa, and can have a flat surface. In this example, the height can represent a vertical separation distance from the first substrate 111. The bottom portion CCEb of the cathode connection electrode CCE can be flatly disposed on the upper surface of the interlayer insulation layer ILDP in the transmissive area TA.

The cathode connection electrode CCE can include at least one side portion CCEc, CCEd, CCEc, and CCEf disposed in the transmissive area TA. The at least one side portion CCEc, CCEd, CCEc, and CCEf of the cathode connection electrode CCE can be extended perpendicularly or outwardly inclined from the bottom portion CCEb in the transmissive area TA. The at least one side portion CCEc, CCEd, CCEc, and CCEf of the cathode connection electrode CCE can extend toward the second substrate 112.

The cathode connection electrode CCE can include at least one of the first side portion CCEc connecting the connection portion CCEa and the bottom portion CCEb, the second side portion CCEd facing the first side portion CCEc, and the third side portion CCEe and the fourth side portion CCEf connecting the first side portion CCEc and the second side portion CCEd. The first side portion CCEc of the cathode connection electrode CCE can be extended along the side surface of the first insulation layer PAS1. Accordingly, an outer side surface OS of the first side portion CCEc of the cathode connection electrode CCE can contact at least a portion of the side surface of the first insulation layer PAS1.

Since the first insulation layer PAS1 is not disposed in the transmissive area TA, an outer side surface OS of each the second side portion CCEd, the third side portion CCEe, and the fourth side portion CCEf of the cathode connection electrode CCE can be exposed without contacting the side surface of the first insulation layer PAS1.

As shown in FIGS. 17 and 18, the first side portion CCEc, the second side portion CCEd, the third side portion CCEe, and the fourth side portion CCEf of the cathode connection electrode CCE can have different perpendicular heights depending on their position.

Specifically, the cathode connection electrode CCE can include a first side disposed in the non-transmissive area NTA and a second side facing the first side. The second side can be disposed in the transmissive area TA. The cathode connection electrode CCE can include the connection portion CCEa on the first side and the second side portion CCEd on the second side.

A width W4 of the first side of the cathode connection electrode CCE can be different from a width W5 of the second side of the cathode connection electrode CCE. In one embodiment, the width of the cathode connection electrode CCE can increase or decrease from the first side to the second side. In one example, as shown in FIG. 16, the width of the cathode connection electrode CCE can increase from the first side to the second side. That is, the width of the cathode connection electrode CCE can increase as it moves away from the non-transmissive area NTA. In another example, the width of the cathode connection electrode CCE can decrease from the first side to the second side. That is, the width of the cathode connection electrode CCE can decrease as it moves away from the non-transmissive area NTA.

As described above, as illustrated in FIGS. 17 and 18, when the cathode connection electrode CCE is formed with different widths depending on the position, the perpendicular heights of the second side portion CCEd, the third side portion CCEe, and the fourth side portion CCEf can vary depending on the position. FIG. 17 shows a cross-sectional view of the cathode connection electrode CCE at a position spaced apart from the first side of the cathode connection electrode CCE by a first distance S1, and FIG. 18 shows a cross-sectional view of the cathode connection electrode CCE at a position spaced apart from the first side of the cathode connection electrode CCE by a second distance S2 greater than the first distance S1.

When the width of the cathode connection electrode CCE increases as the position of the cathode connection electrode CCE moves away from the first side, the cathode connection electrode CCE can have a relatively small width as the position of the cathode connection electrode CCE approaches the first side. The smaller width of the cathode connection electrode CCE can result in a smaller perpendicular height H of the at least one side portion CCEd, CCEe, and CCEf. The cathode connection electrode CCE can have the perpendicular height H of the at least one side portion CCEd, CCEe, and CCEf smaller than the thickness T1 of the first insulation layer PAS1. As the perpendicular height H of the at least one side portion CCEd, CCEe, and CCEf is smaller, the cathode connection electrode CCE cannot be easily contacted with the second electrode 140 of the light emitting device ED, and even if it is contacted, the electrical connection can become unstable due to a small contact area.

On the other hand, when the width of the cathode connection electrode CCE increases as the position of the cathode connection electrode CCE moves away from the first side, the cathode connection electrode CCE can have a relatively wide width as the position of the cathode connection electrode CCE moves away from the first side. The cathode connection electrode CCE cannot have the perpendicular height H of at least one of the side portions CCEd, CCEe, and CCEf larger than a certain value. In the cathode connection electrode CCE formed according to the manufacturing process illustrated in FIGS. 10A to 10G described above, the perpendicular height H of the at least one side portion CCEd, CCEe, and CCEf cannot be larger than the thickness T1 of the first insulation layer PAS1. Accordingly, as shown in FIG. 18, when the width of the cathode connection electrode CCE becomes a certain value or more, the upper portions CCEg and CCEh extending parallel to the first substrate 111 can be further formed from the at least one side portion CCEd, CCEe and CCEf.

The light emission layer 130 of the light emitting device ED can be disposed to contact the inner side surface IS of each of the side portions CCEe and CCEf, the bottom portion CCEb, and the upper portions CCEg and CCEh of the cathode connection electrode CCE. The second electrode 140 of the light emitting device ED can be disposed to cover the light emission layer 130 on the light emission layer 130 disposed in the cathode connection electrode CCE. In this example, the second electrode 140 can be difficult to be formed up to the outer side surface OS of the side portions CCEe and CCEf of the cathode connection electrode CCE because the upper portions CCEg and CCEh of the cathode connection electrode CCE can extend out of the outer side surface OS of the side portions CCEe and CCEf of the cathode connection electrode CCE. Accordingly, the cathode connection electrode CCE cannot be easily contacted with the second electrode 140 of the light emitting device ED, and even if it is contacted, the electrical connection can be unstable due to a small contact area.

As shown in FIGS. 17 and 18, the cathode connection electrode CCE can be formed with a small width in the opening area OA of the first insulation layer PAS1 illustrated in FIG. 10B or can be formed with a larger width than the opening area OA of the first insulation layer PAS1 in illustrated FIG. 10B. In this example, the cathode connection electrode CCE cannot be easily contacted with the second electrode 140 of the light emitting device ED, and even if it is contacted, the electrical connection can be unstable due to a small contact area.

The opening area OA of the first insulation layer PAS1 in illustrated FIG. 10B can be formed larger or smaller than the design due to a process error. Alternatively, the cathode connection electrode CCE can be formed larger or smaller than the design due to a process error. As a result, the cathode connection electrode CCE can be formed with a small width in the opening area OA of the first insulation layer PAS1 in illustrated FIG. 10B or can be formed with a larger width than the opening area OA of the first insulation layer PAS1 in illustrated FIG. 10B. In this example, when the cathode connection electrode CCE is designed with a certain width, the cathode connection electrode CCE cannot be easily contacted with the second electrode 140 of the light emitting device ED at all positions, and accordingly, the electrical connection between the cathode connection electrode CCE and the second electrode 140 can become unstable.

In the transparent display panel 110 according to another embodiments of the present disclosure, since the cathode connection electrode CCE can be a transparent electrode, it is possible to feely design the cathode connection electrode. The cathode connection electrode CCE according to another embodiments of the present disclosure can be formed to have different widths depending on the position, and thus the cathode connection electrode can contact the second electrode 140 of the light emitting device ED at a predetermined position even if a process error occurs.

In one example, as shown in FIG. 17, the cathode connection electrode CCE can be formed to have a width smaller than the opening area OA of the first insulation layer PAS1 in illustrated FIG. 10B at a position spaced apart by the first distance S1 from the first side. Accordingly, the cathode connection electrode CCE cannot be easily contacted with the second electrode 140 of the light emitting device ED at the position spaced apart by the first distance S1 from the first side.

Further, as shown in FIG. 18, the cathode connection electrode CCE can be formed to have a width larger than the opening area OA of the first insulation layer PAS1 in illustrated FIG. 10B at a position spaced apart by the second distance S2 from the first side. Accordingly, the cathode connection electrode CCE cannot be easily contacted with the second electrode 140 of the light emitting device ED at a position spaced apart by the second distance S2 from the first side.

However, the cathode connection electrode CCE can be formed to have an optimal width equal to the opening area OA of the first insulation layer PAS1 in illustrated FIG. 10B at the at least one of the positions where the separation distance from the first side is greater than the first distance S1 and less than the second distance S2. Thus, it is possible to ensure that the cathode connection electrode CCE is stably contacted with the second electrode 140 of the light emitting device ED at the at least one position, even if a process error occurs.

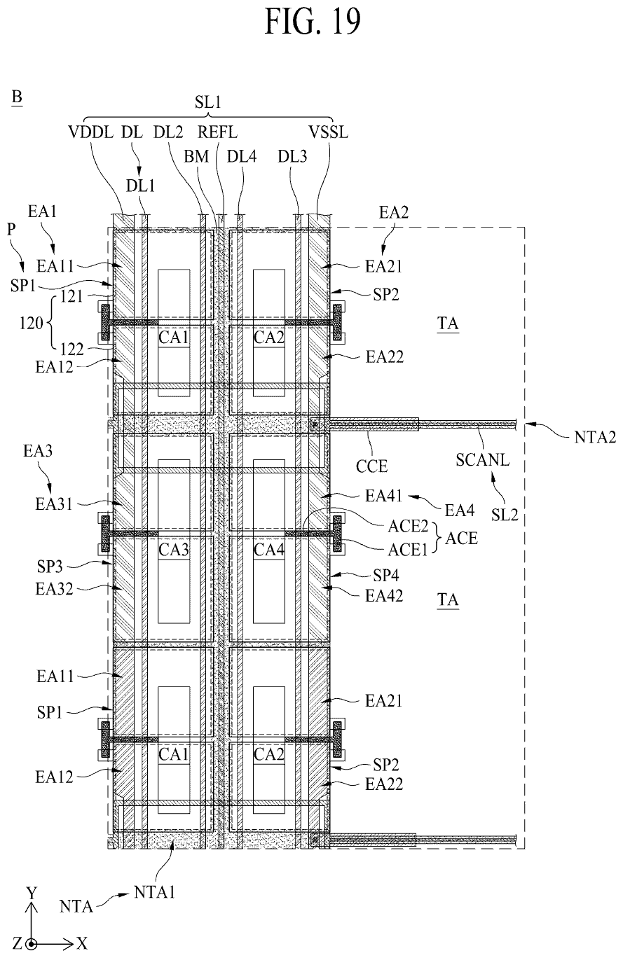

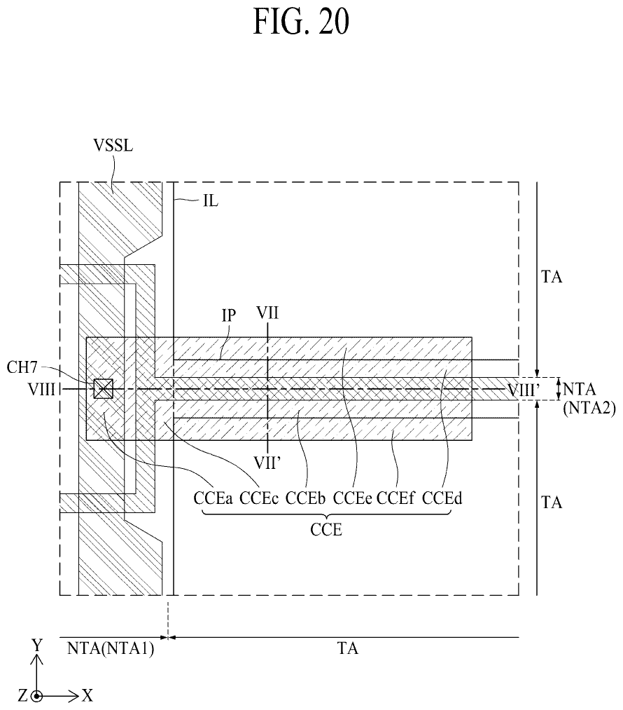

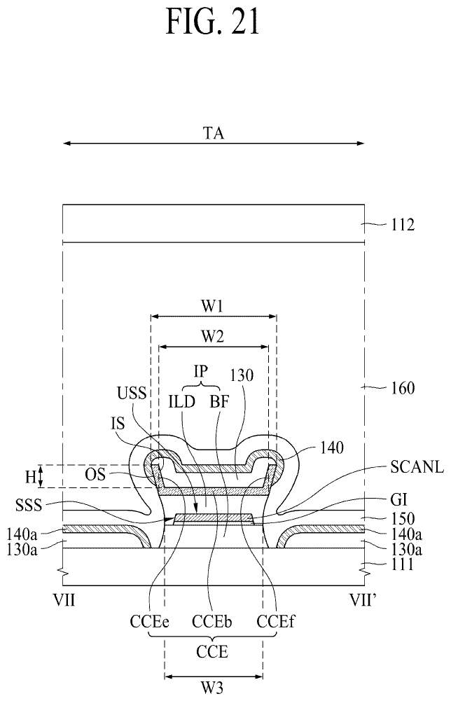

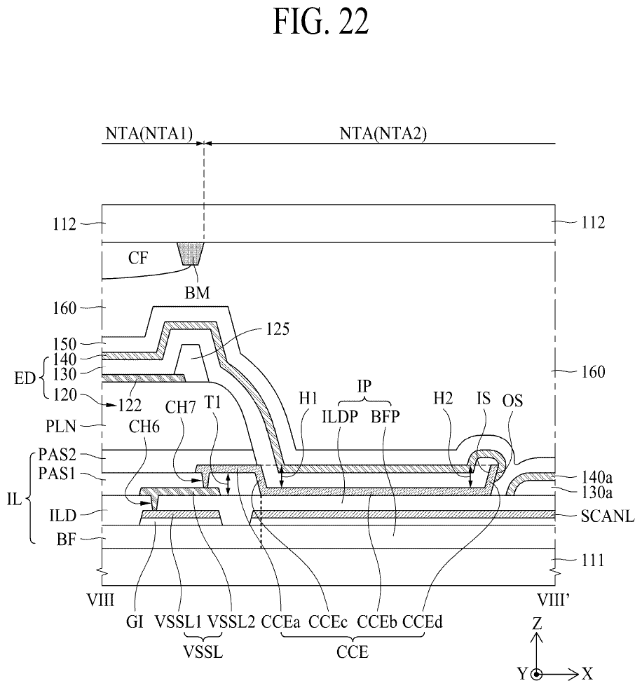

FIG. 19 is a drawing illustrating another embodiment of the plurality of sub-pixels and plurality of signal lines disposed in the portion B illustrated in FIG. 3, FIG. 20 is an enlarged plan view of another embodiment of a common power line and cathode connection electrode, FIG. 21 is a cross-sectional view illustrating one embodiment of VII-VII′ illustrated in FIG. 20, and FIG. 22 is a cross-sectional view illustrating one embodiment VIII-VIII′ illustrated in FIG. 20.

The cathode connection electrode CCE illustrated in FIGS. 4 and 7 to 10 is described as extending from the first non-transmissive area NTA1 to the transmissive area TA, but is not necessarily limited thereto. The cathode connection electrode CCE can also be disposed in the second non-transmissive area NTA2. Hereinafter, differences between the cathode connection electrode CCE illustrated in FIGS. 19 to 22 and the cathode connection electrode CCE illustrated in FIGS. 4 and FIGS. 7 to 10 will be described in detail, and substantially identical content can be omitted.

The cathode connection electrode CCE can be electrically connected to the common power line VSSL in the first non-transmissive area NTA1. When the cathode connection electrode CCE is disposed on the same layer as the anode connection electrode ACE, the cathode connection electrode CCE can be electrically connected to the common power line VSSL via the seventh contact hole CH7 penetrating the first insulation layer PAS1.

The cathode connection electrode CCE can be disposed in the second non-transmissive area NTA2 disposed between two adjacent transmissive areas TA. The cathode connection electrode CCE can be disposed to overlap the scan line SCANL in the second non-transmissive area NTA2, and can be extended along the scan line SCANL in the second direction (e.g., the X-axis direction).

At least one side of the cathode connection electrode CCE can contact the second electrode 140 of the light emitting device ED, and thus cathode connection electrode CCE can be electrically connected to the second electrode 140 of the light emitting device ED.

Specifically, the cathode connection electrode CCE can be disposed on the plurality of insulation layers IL and IP and can be extended along the scan line SCANL disposed between two adjacent transmissive areas TA. The cathode connection electrode CCE can be disposed on the scan line SCANL. The scan line SCANL can be disposed between the plurality of insulation layers IL and IP. In one example, the scan line SCANL can be formed of the same material on the same layer as the gate electrode GE of the driving transistor DTR. In this example, the scan line SCANL can be disposed between the interlayer insulation layer ILD and the buffer layer BF. Also, the gate insulation layer GI can be further disposed between the scan line SCANL and the buffer layer BF.

The cathode connection electrode CCE can be extended by a predetermined length on the scan line SCANL. Accordingly, the scan line SCANL can at least partially overlap the cathode connection electrodes CCE, but other portions cannot overlap the cathode connection electrode CCE. Although not shown in FIG. 22, the bank 125 can be disposed on the scan line SCANL in an area where the scan line SCANL does not overlap with the cathode connection electrode CCE.

The number of insulation layers IL disposed below the cathode connection electrode CCE in the first non-transmissive area NTA1 and the number of insulation layers IP disposed below the cathode connection electrode CCE in the second non-transmissive area NTA21 can be different. The number of insulation layers IP disposed below the cathode connection electrode CCE in the first non-transmissive area NTA1 can be less than the number of insulation layers IL disposed below the cathode connection electrode CCE in the second non-transmissive area NTA2. In one example, the insulation layer IL including the buffer layer BF, the interlayer insulation layer ILD, and the first insulation layer PAS1 can be disposed below the cathode connection electrode CCE in the first non-transmissive area NTA1. On the other hand, the insulation layer IP including the buffer layer BF and the interlayer insulation layer ILD can be disposed below the cathode connection electrode CCE in the second non-transmissive area NTA2. The gate insulation layer GI can be further disposed below the cathode connection electrode CCE in the first non-transmissive area NTA1 and the second non-transmissive area NTA2.

Hereinafter, for convenience of description, it will be described that the insulation layer IL disposed below the cathode connection electrode CCE in the first non-transmissive area NTA1 includes the buffer layer BF, the interlayer insulation layer ILD, and the first insulation layer PAS1, and that the insulation layer IP disposed below the cathode connection electrode CCE in the second non-transmissive area NTA2 includes the buffer layer BF and the interlayer insulation layer ILD. However, the number of insulation layers IP disposed below the cathode connection electrode CCE in the second non-transmissive area NTA2 should be less than the number of insulation layers IL disposed below the cathode connection electrode CCE in the first non-transmissive area NTA1, but is not necessarily limited thereto.

Since, the number of insulation layers IP disposed below the cathode connection electrode CCE in the second non-transmissive area NTA1 can be less than the number of insulation layers IL disposed below the cathode connection electrode CCE in the first non-transmissive area NTA1, the cathode connection electrode CCE cannot be formed flat and can have a concave shape toward the first substrate 111.

As shown in FIG. 20, the cathode connection electrode CCE can include the connection portion CCEa, the bottom portion CCEb, and at least one side portion CCEc, CCEd, CCEe, and CCEf extending from the bottom portion CCEb.

The connection portion CCEa of the cathode connection electrode CCE is disposed on the plurality of insulation layers IL in the first non-transmissive area NTA1, and can be connected to the common power line VSSL via the seventh contact hole CH7 penetrating a portion of the plurality of insulation layers ILs. The connection portion CCEa of the cathode connection electrode CCE can be connected to the common power line VSSL via the seventh contact hole CH7 penetrating the first insulation layer PAS1 of the plurality of insulation layers IL.

The bottom portion CCEb of the cathode connection electrode CCE can be disposed on at least one insulation layer IP in the second non-transmissive area NTA2. The bottom portion CCEb of the cathode connection electrode CCE can be formed to have a width greater than a width of the second non-transmissive area NTA2. The width of the second non-transmissive area NTA2 can be determined according to an area in which the scan line SCANL is formed. In this example, the bottom portion CCEb of the cathode connection electrode CCE can at least partially overlap the transmissive area TA. The bottom portion CCEb of the cathode connection electrode CCE can be disposed to have a height lower than that of the connection portion CCEa, and can have a flat surface. In this case, the height can represent a vertical separation distance from the first substrate 111. The bottom portion CCEb of the cathode connection electrode CCE can be flatly disposed on the upper surface of the interlayer insulation layer ILD.

The cathode connection electrode CCE can include at least one side portion CCEc, CCEd, CCEc, and CCEf disposed in the second non-transmissive area NTA2 or the transmissive area TA. The at least one side portion CCEc, CCEd, CCEe, and CCEf of the cathode connection electrode CCE can be extended perpendicularly or outwardly inclined from the bottom portion CCEb. The at least one side portion CCEc, CCEd, CCEe, and CCEf of the cathode connection electrode CCE can be extended toward the second substrate 112.

The cathode connection electrode CCE can include at least one of the first side portion CCEc connecting the connection portion CCEa and the bottom portion CCEb, the second side portion CCEd facing the first side portion CCEc, and the third side portion CCEe and the fourth side portion CCEf connecting the first side portion CCEc and the second side portion CCEd. The first side portion CCEc of the cathode connection electrode CCE can be extended along the side surface of the first insulation layer PAS1. Accordingly, an outer side surface OS of the first side portion CCEc of the cathode connection electrode CCE can contact the side surface of the first insulation layer PAS1. The first side portion CCEc of the cathode connection electrode CCE can have a perpendicular height corresponding to a thickness of the first insulation layer PAS1.

Since the first insulation layer PAS1 is not disposed in the transmissive area TA, an outer side surface OS of each of the second side portion CCEd, the third side portion CCEe, and the fourth side portion CCEf of the cathode connection electrode CCE can be exposed without contacting the side surface of the first insulation layer PAS1. The second side portion CCEd, the third side portion CCEe, and the fourth side portion CCEf of the cathode connection electrode CCE do not contact the side surface of the first insulation layer PAS1, but can have a perpendicular height H corresponding to a thickness of the first insulation layer PAS1, such as the first side portion CCEc.

The insulation pattern IP including the interlayer insulation pattern ILDP and the buffer pattern BFP can be disposed below the cathode connection electrode CCE. The cathode connection electrode CCE and the insulation pattern IP can have an undercut structure. That is, a width W3 of at least a portion of the insulation pattern IP can be smaller than the width W1 of the cathode connection electrode CCE. At least one side portion CCEe and CCEf of the cathode connection electrode CCE can be formed to be inclined outwardly from the bottom portion CCEb. Accordingly, the bottom portion CCEb of the cathode connection electrode CCE can have a width W2 less than the entire width W1 of the cathode connection electrode CCE. The width W3 of at least a portion of the insulation pattern IP can be smaller than the width W2 of the bottom portion CCEb of the cathode connection electrode CCE. The widths W1, W2, and W3 can be a length in the first direction (e.g., the Y-axis direction), but are not necessarily limited thereto. The widths W1, W2, and W3 can be a length in the second direction (e.g., the X-axis direction).

The scan line SCANL can be disposed in the insulation pattern IP. In one example, the scan line SCANL can be disposed between the interlayer insulation pattern ILDP and the buffer pattern BFP. The interlayer insulation pattern ILDP can be disposed to cover an upper surface USS and a side surface SSS of the scan line SCANL between the cathode connection electrode CCE and the scan line SCANL. A width W6 of the scan line SCANL can be smaller than the width W1 of the cathode connection electrode CCE. The width W6 of the scan line SCANL can be smaller than the width W3 of the insulation pattern IP.

The insulation pattern IP can overlap the cathode connection electrode CCE and can be disposed along the cathode connection electrode CCE. Further, the insulation pattern IP can overlap the scan line SCANL and can be provided along the scan line SCANL.

The light emission layer 130 of the light emitting device ED can be disposed on the cathode connection electrode CCE. The light emission layer 130 can be disconnected by the cathode connection electrode CCE. The light emission layer 130 can be a common layer disposed in common to the sub-pixels SP1, SP2, SP3, and SP4. The light emission layer 130 can be disposed not only on the first non-transmissive area NTA1, but also on the second non-transmissive area NTA2 and the transmissive area TA.

The light emission layer 130 can be disconnected by at least one side portion CCEe and CCEf of the cathode connection electrode CCE protruded toward the second substrate 112 in the second non-transmissive area NTA2 or the transmissive area TA. Some of the light emission layers 130 can be disposed to contact the bottom portion CCEb of the cathode connection electrode CCE and the inner side surface IS of each of the side portions CCEe and CCEf of the cathode connection electrode CCE. Another part of the light emission layer 130a can be disposed to be disconnected from the light emission layer 130 disposed on the cathode connection electrode CCE without being continuous and thus, another part of the light emission layer 130a can contact the upper surface of the exposed first substrate 111. In this example, an outer side surface OS of the side portions CCEe and CCEf of the cathode connection electrode CCE can be exposed without being covered by the light emission layer 130.

The second electrode 140 of a light emitting device ED can be disposed on the light emission layer 130. The second electrode 140 can be disconnected by the cathode connection electrode CCE. The second electrode 140 can be a common layer disposed in common to the sub-pixels SP1, SP2, SP3, and SP4. The second electrode 140 can be disposed not only on the first non-transmissive area NTA1, but also on the second non-transmissive area NTA2 and the transmissive area TA.

These second electrode 140 can be disconnected by at least one side portion CCEe and CCEf of the cathode connection electrode CCE and the insulation pattern IP. The at least one side portion CCEe and CCEf of the cathode connection electrode CCE and the insulation pattern IP are protruded toward the second substrate 112 in the second non-transmissive area NTA2 or the transmissive area TA. A portion of the second electrode 140 can be disposed to cover the light emission layer 130 on the light emission layer 130 disposed in the cathode connection electrode CCE. The second electrode 140 can have a better step coverage than the light emission layer 130 including organic material, and thus can be deposited to have larger area than that of the light emission layer 130. Accordingly, the portion of the second electrode 140 can be disposed on the outer side surface OS of the side portions CCEe and CCEf of the cathode connection electrodes CCE that are not covered by the light emission layer 130 and are exposed. The at least a portion of the outer side surface OS of the side portions CCEe and CCEf of the cathode connection electrodes CCE can contact the second electrode 140 of the light emitting device ED.

Meanwhile, another second electrode 140a can be disposed to be disconnected from the second electrode 140 disposed on the cathode connection electrode CCE without being continuous, and thus another second electrode 140a can contact the light emission layer 130a disposed on the upper surface of the exposed first substrate 111.

As a result, an end of the cathode connection electrode CCE can be electrically connected to the common power line VSSL, and the outer side surface OS of at least one of the side portions CCEd, CCEe, and CCEf of the cathode connection electrode CCE can be electrically connected to the second electrode 140 of the light emitting device ED. Accordingly, the second electrode 140 of the light emitting device ED can be supplied with the second power from the common power line VSSL through the cathode connection electrode CCE.

The transparent display panel 110 according to another embodiment of the present disclosure can electrically connect the second electrode 140 of the light emitting device ED and the common power line VSSL using the cathode connection electrode CCE. In the transparent display panel 110 according to another embodiment of the present disclosure, the cathode connection electrode CCE can include a transparent conductive material. Thereby, in the transparent display panel 110 according to another embodiment of the present disclosure, even though the cathode connection electrode CCE is disposed in the transmissive area TA, there can be no decrease in the light transmittance of the transmissive area TA due to the cathode connection electrode CCE.

Moreover, in the transparent display panel 110 according to another embodiment of the present disclosure, since the cathode connection electrode CCE can be disposed in the second non-transmissive area NTA2 in which the scan line SCANL is disposed, it is possible to provide a flat surface without a step difference inside the transmissive area TA. Thereby, the transparent display panel 110 according to another embodiment of the present disclosure can prevent external light passing through the transmissive area TA from being diffracted or refracted.

Moreover, in the transparent display panel 110 according to another embodiment of the present disclosure, the cathode connection electrode CCE can have at least one side portion CCEd, CCEe, and CCEf, and the second electrode 140 of the light emitting device ED can be contacted on the outer side surface OS of the at least one side portion CCEd, CCEe, and CCEf. In the transparent display panel 110 according to another embodiment of the present disclosure, a contact area between the cathode connection electrode CCE and the second electrode 140 of the light emitting device ED can be increased. Thereby, in the transparent display panel 110 according to another embodiment of the present disclosure, the cathode connection electrode CCE and the second electrode 140 of the light emitting device ED can stably contact.

Furthermore, the transparent display panel 110 according to another embodiment of the present disclosure can increase transparency by removing the buffer layer BF, the interlayer insulation layer ILD, the first insulation layer PAS1, the second insulation layer PAS2, and the planarization layer PLN in the transmissive area TA.

In, the present disclosure, the second electrode of the light emitting device and the common power line can be electrically connected by using the cathode connection electrode. In the present disclosure, since the cathode connection electrode can be made of a transparent conductive material, the light transmittance of the transmissive area can be prevented from being reduced.

Moreover, in the present disclosure, an external light passing through the transmissive area can be prevented from being diffracted or refracted.

Moreover, in the present disclosure, the second electrode of the light emitting device can be contacted with an outer side surface of at least one side portion of the cathode connection electrode, thereby increasing the contact area between the cathode connection electrode and the second electrode of the light emitting device. Thereby, the second electrode of the light emitting device can be stably contacted with the cathode connection electrode.

Moreover, in the present disclosure, transparency can be increased by removing insulation layers within the transmissive area.

Moreover, in the present disclosure, since the planarization layer cannot be disposed in the transmissive area, moisture can be prevented from penetrating the cathode connection electrode through the planarization layer. Thus, in the present disclosure, the lifespan of the display device can be extended, and as the lifespan of the display device increases, the manufacturing process for producing a new display device can be reduced, thereby reducing the generation of greenhouse gases due to the manufacturing process, thus implementing ESG Environment/Social/Governance.

Moreover, in the present disclosure, the cathode connection electrode can be simultaneously disposed on the same layer as the anode connection electrode or the pad. In this way, in the present disclosure, process optimization can be implemented and production energy can be reduced.

The above-described feature, structure, and effect of the present disclosure are included in at least one embodiment of the present disclosure, but are not limited to only one embodiment. Furthermore, the feature, structure, and effect described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure.

The various embodiments described above can be combined to provide further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A transparent display device, comprising:
a first area in which a plurality of sub-pixels are disposed;
a second area in which the plurality of sub-pixels are not disposed;
a light emitting device disposed in the each of the plurality of sub-pixels, the light emitting device including a first electrode, a light emission layer, and a second electrode;
a power line extending from the first area in a first direction; and
a cathode connection electrode electrically connected to the power line in the first area and extended in a second direction toward the second area to be electrically connected to the second electrode of the light emitting device in the second area,
wherein the cathode connection electrode includes a bottom portion and at least one side portion extended from the bottom portion.

2. The transparent display device of claim 1, wherein the at least one side portion of the cathode connection electrode is either perpendicular to the bottom portion or outwardly inclined from the bottom portion.

3. The transparent display device of claim 1, wherein the at least one side portion of the cathode connection electrode contacts the second electrode of the light emitting device in the second area.

4. The transparent display device of claim 3, wherein at least a portion of an outer side surface of the at least one side portion of the cathode connection electrode contacts the second electrode of the light emitting device.

5. The transparent display device of claim 1, wherein the cathode connection electrode comprises transparent conductive materials.

6. The transparent display device of claim 1, wherein the second area is a transmissive area through which external light passes.

7. The transparent display device of claim 1, further comprising:
at least one insulation layer disposed below the cathode connection electrode in the second area.

8. The transparent display device of claim 7, wherein the at least one insulation layer comprises inorganic materials.

9. The transparent display device of claim 7, wherein the at least one insulation layer has a width smaller than a width of the cathode connection electrode.

10. The transparent display device of claim 9, wherein the at least one insulation layer has a width smaller than a width of the bottom portion of the cathode connection electrode.

11. The transparent display device of claim 7, wherein the at least one insulation layer overlaps the cathode connection electrode in the second area to be disposed along the cathode connection electrode and has a same shape as the cathode connection electrode on the plane in the second area.

12. The transparent display device of claim 1, further comprising a protection layer disposed on the cathode connection electrode.

13. The transparent display device of claim 12, wherein the protection layer overlaps the cathode connection electrode in the second area to be disposed along the cathode connection electrode and has a same shape as the cathode connection electrode on the plane in the second area.

14. The transparent display device of claim 12, wherein the protection layer comprises inorganic materials.

15. The transparent display device of claim 1,
wherein the cathode connection electrode comprises a first side and a second side facing the first side, and
wherein, from a plan view, a width at the first side of the cathode connection electrode and a width at the second side of the cathode connection electrode are different from each other.

16. The transparent display device of claim 15, wherein a width of the cathode connection electrode either increases or decreases from the first side toward the second side.

17. The transparent display device of claim 1, further comprising a signal line extended in the second direction and supplying signal to each of the plurality of sub-pixels,
wherein the cathode connection electrode overlaps the signal line.

18. The transparent display device of claim 17, wherein a width of the signal line is smaller than a width of the cathode connection electrode.

19. The transparent display device of claim 17, further comprising an insulation layer disposed between the signal line and the cathode connection electrode and covering an upper surface and a side surface of the signal line.

20. The transparent display device of claim 1, further comprising:
a driving transistor including an active layer, a gate electrode, source electrode, and a drain electrode; and
an anode connection electrode disposed between the driving transistor and the first electrode of the light emitting device and electrically connected to one of the source electrode and the drain electrode,
wherein the first electrode of the light emitting device is electrically connected to one of the source electrode and the drain electrode of the driving transistor through the anode connection electrode, and
wherein the cathode connection electrode comprises a same material as the anode connection electrode.

21. A transparent display device, comprising:
a substrate including a display area and a non-display area, the display area having a transmissive area and a non-transmissive area;
a light emitting device disposed in the non-transmissive area on the substrate, the light emitting device comprising a first electrode, a light emission layer, and a second electrode;
a power line extended in a first direction in the non-transmissive area; and
a cathode connection electrode electrically connected to the power line, extended in the second direction toward the transmissive area, the cathode connection electrode including transparent conductive materials,
wherein the second electrode of the light emitting device is extended from the non-transmissive area to the transmissive area, and is electrically connected to the cathode connection electrode in the transmissive area.

22. The transparent display device of claim 21, further comprising:
a driving transistor disposed between the substrate and the first electrode of the light emitting device, the driving transistor including an active layer, a gate electrode, a source electrode, and a drain electrode; and
an anode connection electrode disposed between the driving transistor and the first electrode of the light emitting device, and electrically connected to one of the source electrode and the drain electrode of the driving transistor,
wherein the first electrode is electrically connected to one of the source electrode and the drain electrode of the driving transistor through the anode connection electrode.

23. The transparent display device of claim 22, wherein the cathode connection electrode comprises the same materials as the anode electrode.

24. The transparent display device of claim 21, further comprising:
a pad disposed in the non-display area, the pad including a first layer and a second layer disposed to cover the first layer,
wherein the cathode connection electrode comprises the same materials as the second layer of the pad.

25. The transparent display device of claim 21, wherein the cathode connection electrode comprises a bottom portion and a side portion perpendicular to the bottom portion or outwardly inclined from the bottom portion.

26. The transparent display device of claim 25, wherein at least a portion of the outer side surface of the side portion of the cathode connection electrode contacts the second electrode of the light emitting element in the transmissive area.

27. The transparent display device of claim 25, wherein the second electrode of the light emitting device is disconnected by the cathode connection electrode in the transmissive area.

28. The transparent display device of claim 25, wherein the light emission layer is extended from the non-transmissive area to the transmissive area, and contacts an inner side surface of each of the bottom portion and the side portion of the cathode connection electrode in the transmissive area.

29. The transparent display device of claim 25, wherein the light emission layer of the light emitting device is disconnected by the cathode connection electrode in the transmissive area.

30. The transparent display device of claim 21, further comprising at least one insulation pattern disposed between the substrate and the cathode connection electrode in the transmissive area.

31. The transparent display device of claim 30, wherein the at least one insulation pattern and the cathode connection electrode have an undercut structure.

32. The transparent display device of claim 30, wherein the at least one insulation pattern is disposed to expose an upper surface of the substrate in an area where the cathode connection electrode is not disposed in the transmissive area.

33. A transparent display device, comprising:
a transmissive area and a non-transmissive area adjacent to the transmissive area;
a plurality of sub-pixels disposed in the non-transmissive area;
a light emitting device disposed in the each of the plurality of sub-pixels, the light emitting device including a first electrode, a light emission layer, and a second electrode;
a power line overlapping the non-transmissive area from a plan view; and
a cathode connection electrode overlapping both the transmissive area and the non-transmissive area from a plan view,
wherein the cathode connection electrode extends from the transmissive area to the non-transmissive area and overlaps with the power line from a plan view.

34. The transparent display device of claim 33, wherein the cathode connection electrode includes a bottom portion, at least one side portion extended from the bottom portion, a connection portion extended from the at least one side portion,
wherein the at least one side portion is inclined relative to the bottom portion at a first inclination angle, and
wherein the connection portion of the cathode connection electrode overlaps with the power line from a plan view.

35. The transparent display device of claim 34, wherein the power line includes a plurality of metal layers, the plurality of metal layers including a first metal layer and a second metal layer on the first metal layer,
wherein the second metal layer is on a same layer as the bottom portion of the cathode connection electrode, and
wherein the first metal layer is spaced apart from the bottom portion of the cathode connection electrode.

36. The transparent display device of claim 34, wherein the second electrode of the light emitting device extends from the non-transmissive area to the transmissive area,
wherein the second electrode of the light emitting device directly contacts the at least one side portion of the cathode connection electrode.

37. The transparent display device of claim 34, wherein the second electrode of the light emitting device extends from the non-transmissive area to the transmissive area,
wherein, from a cross-sectional view, the at least one side portion of the cathode connection electrode includes an inner side surface and an outer side surface opposite and facing the inner side surface,
wherein the second electrode of the light emitting device directly contacts the outer side surface of the at least one side portion of the cathode connection electrode and extends towards the bottom portion of the cathode connection electrode, and
wherein the second electrode of the light emitting device is spaced apart from the inner side surface of the at least one side portion of the cathode connection electrode.

38. The transparent display device of claim 37, further comprising:
a protection layer on the cathode connection electrode,
wherein the light emitting layer of the light emitting device extends from the non-transmissive area to the transmissive area, and
wherein the protection layer directly contacts the inner side surface of the at least one side portion and the bottom portion of the cathode connection electrode.
